(19) United States
(12) Patent Application Publication
(10) Pub. No.: US 2026/0018814 A1
(43) Pub. Date: Jan. 15, 2026

(54) RELIABLE COMPACT ORTHOGONAL ELECTRICAL CONNECTOR AND ELECTRONIC SYSTEM THEREOF

(71) Applicant: Amphenol Commercial Products (Chengdu) Co., Ltd., Chengdu (CN)

(72) Inventors: Yunxiang Liu, Chengdu (CN); Chao Hu, Chengdu (CN)

(73) Assignee: Amphenol Commercial Products (Chengdu) Co., Ltd., Chengdu (CN)

(21) Appl. No.: 19/263,190

(22) Filed: Jul. 8, 2025

(30) Foreign Application Priority Data
Jul. 10, 2024 (CN) 202410932211.2
Jul. 10, 2024 (CN) 202421625328.8

(51) Int. Cl. H01R 12/73; H01R 12/72; H05K 7/20

(52) U.S. Cl. CPC H01R 12/737; H01R 12/725; H01R 12/727; H05K 7/20563

(57) ABSTRACT

Reliable compact orthogonal electrical connectors and electronic systems thereof. The connector has a holder with first and second channels, a housing disposed in the first channel and comprising a slot, conductors held by the housing, and a board coupled to conductors. Each conductor has a first mating end disposed in the slot, and a second mating end engaging contact pads at a first edge of the board. The board has a second edge aligned with an opening of the second channel and configured to mate with another connector. The holder has threaded side protrusions for securely mounting to a mainboard. Such a configuration enables a taller, slimmer, light weighted connector, with sufficient/improved mechanical strength, while satisfying physical requirements by EDSFF standard.

### CROSS-REFERENCE TO RELATED APPLICATIONS

This application claims priority to and the benefit of Chinese Patent Application No. 202410932211.2, filed on Jul. 10, 2024. This application also claims priority to and the benefit of Chinese Patent Application No. 202421625328.8, filed on Jul. 10, 2024. The contents of these applications are incorporated herein by reference in their entirety.

### TECHNICAL FIELD

This application relates generally to interconnection systems, such as those including electrical connectors, used to interconnect electronic assemblies.

### BACKGROUND

Electrical connectors are used in many electronic systems. It is generally easier and more cost-effective to manufacture an electronic system as separate electronic subassemblies, such as printed circuit boards (PCBs), which may be joined together by electrical connectors. Having separable electrical connectors enables components of the electronic system manufactured by different manufacturers to be readily assembled. Separable electrical connectors also enable components to be readily replaced after the system is assembled, either to replace defective components or to upgrade the system with higher-performance components.

Conventional arrangements for interconnecting printed circuit boards typically have one printed circuit board used as a motherboard. Other printed circuit boards, referred to as “daughter boards” or “daughter cards”, are connected to the motherboard via electrical connectors so as to achieve the interconnection among these circuit boards.

In high-performance computing systems such as servers and other high-power systems used in data centers, it is often desirable to connect an add-in card to a motherboard as a daughter card. For example, the add-in card may be disposed orthogonally with respect to the motherboard. Multiple add-in cards may be arranged in parallel and adjacent to each other on the motherboard to optimize space and functionality.

Orthogonal electrical connectors can be employed to support the interconnection between the add-in cards and the motherboard. These orthogonal connectors are typically designed and manufactured in accordance with standardized specifications to ensure compatibility with the add-in cards and to meet signal integrity and/or power delivery performance. Examples of such specifications include standards associated with Enterprise and Data Center Standard Form Factor (EDSFF), such as SFF-TA-1002.

### SUMMARY

Aspects of the present disclosure relate to reliable compact orthogonal electrical connectors and electronic systems thereof.

Some embodiments relate to an electrical connector. The electrical connector may include a housing comprising a slot; a plurality of conductive elements, each of the plurality of conductive elements comprising a first mating end disposed in the slot of the housing, and a second mating end opposite to the first mating end; and a board coupled to the plurality of conductive elements. The board may include a first edge portion comprising a plurality of first contact pads aligned in a vertical direction, each of the plurality of first contact pads engaging a respective conductive element of the plurality of conductive elements, and a second edge portion disposed beyond the first edge portion in the vertical direction and a plurality of second contact pads aligned in a lateral direction perpendicular to the vertical direction.

Optionally, the second edge portion of the board is disposed below the slot of the housing.

Optionally, the second mating ends of the plurality of conductive elements are arranged in two rows each extending in the vertical direction and spaced apart from each other in a longitudinal direction perpendicular to the vertical direction and the lateral direction; and the first edge portion is disposed between the two rows of the second mating ends.

Optionally, the housing comprises a first arm portion and a second arm portion spaced apart from each other in the vertical direction; the second mating ends of the plurality of conductive elements are disposed between the first arm portion and the second arm portion; and the first edge portion of the board is held by the first arm portion and the second arm portion therebetween.

Optionally, each of the first arm portion and the second arm portion comprises a passage extending therethrough in a longitudinal direction perpendicular to both the lateral direction and the vertical direction; and the electrical connector comprises a plurality of locking members each disposed in the passage of a respective arm portion and engaging the first edge portion of the board.

Optionally, the first edge portion of the board comprises a plurality of locking pads disposed, each of the plurality of locking pads engaging a respective locking member of the plurality of locking members.

Optionally, the electrical connector comprises a member comprising a first channel and a second channel each extending in the lateral direction and aligned with each other in the vertical direction. The housing is accommodated within the first channel of the member.

Optionally, the first edge portion of the board is disposed within the first channel of the member; and the second edge portion of the board is disposed outside of the member and aligned with the second channel of the member.

Optionally, the board comprises a corner disposed between the first edge portion and the second edge portion; and the member comprises a shelf disposed in the second channel and supporting the corner of the board.

Optionally, the member comprises a bottom surface configured to engage a surface of another board; and a distance from a midpoint of the slot of the housing to the bottom surface of the member is 26.5 mm in the vertical direction.

Some embodiments relate to an electrical connector. The electrical connector may include a member comprising a first channel and a second channel; a housing disposed in the first channel of the member, the housing comprising a card-receiving slot; a plurality of conductive elements, each of the plurality of conductive elements comprising a first mating end disposed in the slot of the housing, and a second mating end disposed outside the slot of the housing; and a board comprising a first edge portion comprising a plurality of first contact pads contacting respective conductive elements of the plurality of conductive elements, and a second edge portion aligned with an opening of the second channel of the member and comprising a plurality of second contact pads.

Optionally, the member comprises a top wall and a bottom wall opposite to each other in a vertical direction, and a separation wall disposed between the top wall and the bottom wall in the vertical direction; and the housing is held in the first channel by the top wall and the separation wall.

Optionally, the member comprises a first receiving groove recessed into the top wall, and a second receiving groove recessed into the separation wall; and the housing comprises a first end face and a second end face opposite to each other in the vertical direction, and a first projection protruding into the first receiving groove of the member, and a second projection protruding into the second receiving groove.

Optionally, the board comprises a board body having a corner, a first side edge extending in the vertical direction, and a second side edge extending in a lateral direction perpendicular to the vertical direction and intersecting the first side edge at the corner; and the first edge portion extends from the first side edge in the lateral direction, and the second edge portion extends from the second side edge in the vertical direction and beyond the first edge portion.

Optionally, the separation wall of the member is indented into the member in the lateral direction; the board body extends from the first channel into the second channel; the corner is disposed in the second channel; and the member comprises a shelf disposed in the second channel and at least partially supporting the second side edge at the corner.

Optionally, the board body comprises a third edge portion extending beyond the first edge portion in the lateral direction; the member comprises a receiving groove recessed into the top wall; and the third edge portion is at least partially disposed in the receiving groove.

Optionally, the separation wall comprises a notch recessed into the separation wall; and the first side edge of the board body is at least partially disposed in the notch.

Optionally, the member comprises a first sidewall and a second sidewall opposite to each other in a longitudinal direction perpendicular to the vertical direction and each extending between the top wall and the bottom wall in the vertical direction; a first protrusion protruding from the bottom wall in the vertical direction; a second protrusion protruding outwardly from the first sidewall in the longitudinal direction and comprising a mounting hole extending in the vertical direction; and a third protrusion protruding outwardly from the second sidewall in the longitudinal direction and offset from the second protrusion in the longitudinal direction, the third protrusion comprising a mounting hole extending in the vertical direction.

Some embodiments relate to an electronic system. The electronic system may include an electrical connector. The electrical connector may include a member comprising a first channel and a second channel, and a housing disposed in the first channel of the member, the housing comprising a card-receiving slot elongated in a vertical direction perpendicular. The member may include a first sidewall and a second sidewall opposite to each other in a longitudinal direction perpendicular to the vertical direction, a first protrusion protruding outwardly from the first sidewall in the longitudinal direction and comprising a mounting hole extending in the vertical direction, and a second protrusion protruding outwardly from the second sidewall in the longitudinal direction and offset from the second protrusion in the longitudinal direction, the second protrusion comprising a mounting hole extending in the vertical direction.

Optionally, the electrical connector is a first electrical connector; the electronic system comprises a plurality of electrical connectors comprising the first electrical connector, the plurality of electrical connectors aligned in a row in the longitudinal direction; and a center-to-center pitch between adjacent electrical connectors of the plurality of electrical connectors is 9.2 mm.

Some embodiments relate to an electrical connector. The electrical connector may comprise: a subassembly housing; a plurality of conductive elements held in the subassembly housing, each conductive element comprising a first mating end, a second mating end opposite to the first mating end, and an intermediate portion joining the first mating end and the second mating end; and a board. The board comprises: a first edge portion; a plurality of first contact pads aligned in a vertical direction; a second edge portion disposed beyond the first edge portion in the vertical direction; and a plurality of second contact pads aligned in the lateral direction on the second edge portion. The second mating end of each of the plurality of conductive elements is disposed on a corresponding one of the plurality of first contact pads.

Optionally, the second mating ends of the plurality of conductive elements are arranged in two rows each extending in the vertical direction, the two rows are opposed to and spaced apart from each other in a longitudinal direction perpendicular to the vertical direction and the lateral direction; and the first edge portion comprises two surfaces opposite to each other in the longitudinal direction, and the plurality of first contact pads are disposed on the two surfaces, the first edge portion is disposed between the two rows of the second mating ends so that each of the two surfaces faces towards a corresponding one of the two rows.

Optionally, the subassembly housing comprises a first face and a first arm portion and a second arm portion each extending from the first face in the lateral direction and spaced apart from each other in the vertical direction, the second mating ends of the plurality of conductive elements protrude out of the first face and are disposed between the first arm portion and the second arm portion, the first arm portion comprises a first groove and the second arm portion comprises a second groove, the first groove and the second groove are arranged to be opposed to each other in the vertical direction and each extend in the lateral direction; and the first edge portion comprises a first end and a second end opposite to each other in the vertical direction, the first end is received in the first groove and the second end is received in the second groove, so that the first edge portion is held by the first arm portion and the second arm portion therebetween.

Optionally, each of the first groove of the first arm portion and the second groove of the second arm portion includes a first wall and a second wall facing towards each other in the longitudinal direction; each of the first arm portion and the second arm portion further comprises a passage extending from an outer side of the corresponding first wall through the first wall into the corresponding groove in the longitudinal direction; and the electrical connector further comprises a plurality of locking members each inserted in the passage of a corresponding arm portion and extending into the corresponding groove to engage with the first edge portion.

Optionally, the board further comprises a plurality of locking pads disposed on the first edge portion, each of the plurality of locking pads faces towards the passage of a corresponding one of the first arm portion and the second arm portion and aligned with the passage, and the corresponding locking member is attached to the locking pad.

Optionally, the second mating end of each of the plurality of conductive elements is attached to a corresponding first contact pad.

Optionally, each of the first arm portion and the second arm portion further comprises a protrusion protruding from the second wall of the corresponding groove into the corresponding groove in the longitudinal direction, the protrusion and the first wall sandwich a corresponding one of the first end and the second end therebetween.

Optionally, the subassembly housing further comprises a second face opposite to the first face in the lateral direction and a slot recessed into the subassembly housing from the second side in the lateral direction, the slot is elongated in the vertical direction, the first mating ends of the plurality of conductive elements are curved into the slot and arranged in two rows each extending in the vertical direction, the two rows are opposed to and spaced apart from each other across the slot in the longitudinal direction.

Optionally, each of the plurality of first contact pads is electrically connected to a corresponding one of the plurality of second contact pads via a corresponding conductive structure of the board.

Optionally, the board is a first board; and the electrical connector further comprises a member accommodating and holding the subassembly housing therein and configured to be mounted onto a second board.

Optionally, the member comprises a first channel and a second channel each extending in the lateral direction, the first channel and the second channel are aligned in the vertical direction and at least partially separated from each other in the vertical direction; the subassembly housing is accommodated and held within the first channel of the member; and when the member is mounted onto the second board, the vertical direction is perpendicular to a surface of the second board, and the second channel is disposed between the first channel and the second board in the vertical direction.

Optionally, the member comprises a top wall and a bottom wall opposite to each other in the vertical direction, and a separation wall disposed between the top wall and the bottom wall in the vertical direction, the separation wall at least partially separates the first channel and the second channel from each other, the first channel is disposed between the top wall and the separation wall, and the second channel is disposed between the separation wall and the bottom wall; and the subassembly housing is held in the first channel by the top wall and the separation wall.

Optionally, the subassembly housing comprises a first end face and a second end face opposite to each other in the vertical direction, and a first projection and a second projection protruding from the first end face and the second end face in the vertical direction, respectively; the member further comprises a first receiving groove recessed into the top wall from the first channel in the vertical direction and extending in the lateral direction, and a second receiving groove recessed into the separation wall from the first channel in the vertical direction and extending in the lateral direction; the member further comprises a first side face and a second side face opposite to each other in the lateral direction, the first channel and the second channel each extending from the first side face through the member to the second side face in the lateral direction, the first channel comprises a first opening at the first side face and a second opening at the second side face; and the subassembly housing is inserted into the first channel from the second opening in the lateral direction, so that the first projection is received in the first receiving groove and engages with an end of the first receiving groove and the second projection is received in the second receiving groove and engages with an end of the second receiving groove so as to restrict further insertion of the subassembly housing towards the first opening in the lateral direction.

Optionally, the subassembly housing further comprises a first snap member disposed at the first end face and a second snap member disposed at the second end face; the member further comprises a first recess recessed into the top wall from the first channel and a second recess recessed into the separation wall from the first channel; and when the first projection and the second projection engage with the end of the first receiving groove and the end of the second receiving groove, respectively, the first snap member snaps into the first recess and the second snap member snaps into the second recess to restrict withdrawal of the subassembly housing towards the second opening in the lateral direction.

Optionally, the first edge portion of the first board is disposed within the first channel; and the second edge portion of the first board is disposed outside of the member and is aligned with an opening of the second channel.

Optionally, the first board comprises a board body having a corner, a first side edge extending in the vertical direction, and a second side edge extending in the lateral direction, the first side edge and the second side edge intersect at the corner, the first edge portion extends from the first side edge in the lateral direction, and the second edge portion extends from the second side edge in the vertical direction; the member further comprises a first side face and a second side face opposite to each other in the lateral direction, the first channel and the second channel each extend from the first side face through the member to the second side face in the lateral direction, the first channel comprises a first opening at the first side face and a second opening at the second side face; an end of the separation wall is indented into the member relative to the second side face in the lateral direction to leave a space between the first channel and the second channel that communicates the first channel and the second channel with each other; the subassembly housing and the first edge portion of the first board are inserted into the first channel from the second opening, and a segment of the board body including the first side edge is disposed in the member and extends from the first channel through the space into the second channel, the corner is disposed in the second channel; and the member further comprises a shelf disposed in the second channel and supporting a segment of the second side edge at the corner in the vertical direction.

Optionally, the shelf comprises a support face for supporting the segment of the second side edge and a pair of projections protruding from the support face in the vertical direction, the pair of projections are spaced apart from each other in a longitudinal direction perpendicular to the vertical direction and the lateral direction and receive and hold the corner therebetween.

Optionally, the board body further comprises a third edge portion extending from the board body oppositely to the second edge portion in the vertical direction and beyond the first edge portion; the member further comprises a third receiving groove recessed into the top wall from the first channel and extending in the lateral direction; and at least a portion of the third edge portion is received in the third receiving groove.

Optionally, the end of the separation wall comprises a notch recessed into the separation wall from the space in the lateral direction, and a segment of the first side edge of the board body is received in the notch.

Optionally, an outer surface of the bottom wall faces towards the surface of the second board when the member is mounted onto the second board; and the member further comprises a first protrusion protruding from the outer surface of the bottom wall in the vertical direction and configured to be placed on the surface of the second board so as to space the outer surface of the bottom wall apart from the surface of the second board.

Optionally, the member further comprises a first sidewall and a second sidewall opposite to each other in a longitudinal direction perpendicular to the vertical direction and the lateral direction, and each extending between the top wall and the bottom wall in the vertical direction; and the member further comprises a second protrusion protruding outwardly from the first sidewall in the longitudinal direction, and a third protrusion protruding outwardly from the second sidewall in the longitudinal direction, the second protrusion and the third protrusion each comprise a mounting hole extending in the vertical direction for receiving a fastener used for securing the member to the second board, the second protrusion and the third protrusion are offset from each other in the longitudinal direction.

Optionally, the first protrusion of the member comprises a bottom surface configured to contact with the surface of the second board, the member further comprises a first side face and a second side face opposite to each other in the lateral direction, the first channel and the second channel each extend from the first side face through the member to the second side face in the lateral direction, the first channel comprises a first opening at the first side face and a second opening at the second side face; the subassembly housing further comprises a second face and a slot recessed into the subassembly housing from the second face in the lateral direction, the slot is elongated in the vertical direction, the first mating ends of the plurality of conductive elements are curved into the slot and arranged in two rows each extending in the vertical direction, the two rows are opposed to and spaced apart from each other across the slot in a longitudinal direction perpendicular to the vertical direction and the lateral direction, the subassembly housing is inserted into the first channel from the second opening in the lateral direction so as to expose the slot at the first opening; and a vertical distance from a midpoint of the slot in the vertical direction to the bottom surface of the first protrusion of the member is 26.5 mm.

Optionally, the member is a metal shell.

Optionally, the second edge portion of the first board is configured to be inserted into another electrical connector mounted on the second board so that each of the plurality of second contact pads is mated with a corresponding conductive element of the another electrical connector.

Optionally, each of the plurality of first contact pads is electrically connected to a corresponding one of the plurality of second contact pads via a corresponding conductive structure of the first board.

Some embodiments relate to an electrical connector. The electrical connector may comprise an subassembly housing; a plurality of conductive elements held in the subassembly housing, each conductive element comprising a first mating end, a second mating end opposite to the first mating end, and an intermediate portion joining the first mating end and the second mating end; a member comprising a first channel and a second channel each extending in a lateral direction, the first channel and the second channel aligned in a vertical direction perpendicular to the lateral direction, the member accommodating and holding the subassembly housing within the first channel; and a board comprising a first edge portion, a plurality of first contact pads on the first edge portion, a second edge portion, and a plurality of second contact pads on the second edge portion. The first edge portion is disposed within the first channel and the second mating end of each of the plurality of conductive elements is disposed on a corresponding one of the plurality of first contact pads. The second edge portion is disposed outside of the member and is aligned with an opening of the second channel.

Optionally, the member comprises a top wall and a bottom wall opposite to each other in the vertical direction, and a separation wall disposed between the top wall and the bottom wall in the vertical direction, the separation wall at least partially separates the first channel and the second channel from each other in the vertical direction, the first channel is disposed between the top wall and the separation wall, and the second channel is disposed between the separation wall and the bottom wall; and the subassembly housing is held in the first channel by the top wall and the separation wall.

Optionally, the subassembly housing comprises a first end face and a second end face opposite to each other in the vertical direction, and a first projection and a second projection protruding from the first end face and the second end face in the vertical direction, respectively; the member further comprises a first receiving groove recessed into the top wall from the first channel in the vertical direction and extending in the lateral direction, and a second receiving groove recessed into the separation wall from the first channel in the vertical direction and extending in the lateral direction; the member further comprises a first side face and a second side face opposite to each other in the lateral direction, the first channel and the second channel each extend from the first side face through the member to the second side face in the lateral direction, the first channel comprises a first opening at the first side face and a second opening at the second side face; and the subassembly housing is inserted into the first channel from the second opening in the lateral direction so that the first projection is received in the first receiving groove and engages with an end of the first receiving groove and the second projection is received in the second receiving groove and engages with an end of the second receiving groove so as to restrict further insertion of the subassembly housing towards to the first opening in the lateral direction.

Optionally, the subassembly housing further comprises a first snap member disposed at the first end face and a second snap member disposed at the second end face; the member further comprises a first recess recessed into the top wall from the first channel and a second recess recessed into the separation wall from the first channel; and when the first projection and the second projection engage with the end of the first receiving groove and the end of the second receiving groove, respectively, the first snap member snaps into the first recess and the second snap member snaps into the second recess to restrict withdrawal of the subassembly housing towards the second opening in the lateral direction.

Optionally, the board comprises a board body having a corner, a first side edge extending in the vertical direction, and a second side edge extending in the lateral direction, the first side edge and the second side edge intersect at the corner, the first edge portion extends from the first side edge in the lateral direction, and the second edge portion extends from the second side edge in the vertical direction and beyond the first edge portion; the member further comprises a first side face and a second side face opposite to each other in the lateral direction, the first channel and the second channel each extend from the first side face through the member to the second side face in the lateral direction, the first channel comprises a first opening at the first side face and a second opening at the second side face; an end of the separation wall is indented into the member relative to the second side face in the lateral direction to leave a space between the first channel and the second channel that communicates the first channel and the second channel with each other; the subassembly housing and the first edge portion of the board are inserted into the first channel from the second opening and a segment of the board body including the first side edge is disposed in the member and extends from the first channel through the space into the second channel, the corner is disposed in the second channel; and the member further comprises a shelf disposed in the second channel and supporting a segment of the second side edge at the corner in the vertical direction.

Optionally, the shelf comprises a support face for supporting the segment of the second side edge and a pair of projections protruding from the support face in the vertical direction, the pair of projections are spaced apart from each other in a longitudinal direction perpendicular to the vertical direction and the lateral direction and receive and hold the corner therebetween.

Optionally, the board body further comprises a third edge portion extending from the board body oppositely to the second edge portion in the vertical direction and beyond the first edge portion; the member further comprises a receiving groove recessed into the top wall from the first channel and extending in the lateral direction; and at least a portion of the third edge portion is received in the receiving groove.

Optionally, the end of the separation wall comprises a notch recessed into the separation wall from the space in the lateral direction, and a segment of the first side edge of the board body is received in the notch.

Optionally, the board is a first board; and the member is configured to be mounted to a second board, when the member is mounted to the second board, the vertical direction is perpendicular to a surface of the second board, and the second channel is disposed between the first channel and the second board in the vertical direction.

Optionally, the member comprises a top wall and a bottom wall opposite to each other in the vertical direction; an outer surface of the bottom wall faces towards the surface of the second board when the member is mounted to the second board; and the member further comprises a first protrusion protruding from the outer surface of the bottom wall in the vertical direction and configured to be placed on the surface of the second board to space the outer surface of the bottom wall apart from the surface of the second board.

Optionally, the member further comprising a first sidewall and a second sidewall opposite to each other in a longitudinal direction perpendicular to the vertical direction and the lateral direction and each extending between the top wall and the bottom wall in the vertical direction; and the member further comprises a second protrusion protruding outwardly from the first sidewall in the longitudinal direction, and a third protrusion protruding outwardly from the second sidewall in the longitudinal direction, the second protrusion and the third protrusion each comprise a mounting hole extending in the vertical direction for receiving a fastener used for securing the member to the second board, the second protrusion and the third protrusion are offset from each other in the longitudinal direction.

Optionally, the second mating ends of the plurality of conductive elements are arranged in two rows each extending in the vertical direction, the two rows are opposite to and spaced apart from each other in a longitudinal direction perpendicular to the vertical direction and the lateral direction, the first edge portion comprises two surfaces opposite to each other in the longitudinal direction, and the plurality of first contact pads are disposed on the two surfaces, the first edge portion is disposed between the two rows of the second mating ends so that each of the two surfaces faces towards a corresponding one of the two rows.

Optionally, the subassembly housing comprises a first face and a first arm portion and a second arm portion each extending from the first face in the lateral direction and spaced apart from each other in the vertical direction, the second mating ends of the plurality of conductive elements protrude from the first face and are disposed between the first arm portion and the second arm portion, the first edge portion is held by the first arm portion and the second arm portion therebetween.

Optionally, the subassembly housing further comprises a second face and a slot recessed into the subassembly housing from the second face in the lateral direction, the slot is elongated in the vertical direction, the first mating ends of the plurality of conductive elements are curved into the slot and arranged in two rows each extending in the vertical direction, the two rows are opposed to and spaced apart from each other across the slot in a longitudinal direction perpendicular to the vertical direction and the lateral direction.

Optionally, the second mating end of each of the plurality of conductive elements is attached to a corresponding first contact pad.

Optionally, the plurality of first contact pads are aligned in the vertical direction on the first edge portion, and the plurality of second contact pads are aligned in the lateral direction on the second edge portion.

Optionally, the member is a metal shell.

Optionally, each of the plurality of first contact pads is electrically connected to a corresponding one of the plurality of second contact pads via a corresponding conductive structure of the board.

Some embodiments relate to an electronic system. The electronic system may comprise: a first board and a first electrical connector. The first electrical connector may comprise: an subassembly housing comprising a slot recessed into the subassembly housing in a lateral direction and elongated in a vertical direction perpendicular to the lateral direction; a plurality of conductive elements held in the subassembly housing, each conductive element comprising a first mating end, a second mating end opposite to the first mating end, and an intermediate portion joining the first mating end and the second mating end, the first mating ends of the plurality of conductive elements exposed in the slot; and a member comprising a first channel and a second channel each extending in the lateral direction, the first channel and the second channel aligned in the vertical direction; wherein the member accommodates and holds the subassembly housing within the first channel, and the member is secured on a surface of the first board so that the vertical direction is perpendicular to the surface of the first board, and the second channel is disposed between the first channel and the first board in the vertical direction.

Optionally, the first electrical connector comprises a second board comprising a first edge portion, a plurality of first contact pads on the first edge portion, a second edge portion, and a plurality of second contact pads on the second edge portion; the first edge portion is disposed within the first channel, and the second mating end of each of the plurality of conductive elements is disposed on a corresponding one of the plurality of first contact pads; and the second edge portion is disposed outside of the member and is aligned in the vertical direction with an opening of the second channel, the second edge portion is configured to be mated with a second electrical connector mounted on the first board.

Optionally, the member comprises a top wall and a bottom wall opposite to each other in the vertical direction, and a separation wall disposed between the top wall and the bottom wall in the vertical direction, the separation wall at least partially separates the first channel and the second channel from each other in the vertical direction, the first channel is disposed between the top wall and the separation wall, and the second channel is disposed between the separation wall and the bottom wall; and the subassembly housing is held in the first channel by the top wall and the separation wall.

Optionally, the second board comprises a board body having a corner, a first side edge extending in the vertical direction, and a second side edge extending in the lateral direction, the first side edge and the second side edge intersect at the corner, the first edge portion extends from the first side edge in the lateral direction, and the second edge portion extends from the second side edge in the vertical direction and beyond the first edge portion; the member further comprises a first side face and a second side face opposite to each other in the lateral direction, the first channel and the second channel each extend from the first side through the member to the second side in the lateral direction, the first channel comprises a first opening at the first side face and a second opening at the second side face; an end of the separation wall is indented into the member relative to the second side face in the lateral direction to leave a space between the first channel and the second channel that communicates the first channel and the second channel with each other; the subassembly housing and the first edge portion of the second board are inserted into the first channel from the second opening, and a segment of the board body including the first side edge is disposed in the member and extends from the first channel through the space into the second channel, the corner is disposed in the second channel; and the member further comprises a shelf disposed in the second channel and supporting a segment of the second side edge at the corner in the vertical direction.

Optionally, the shelf comprises a support face for supporting the segment of the second side edge and a pair of protrusions protruding from the support face in the vertical direction, the pair of protrusions are spaced apart from each other in a longitudinal direction perpendicular to the vertical direction and the lateral direction and receive and hold the corner therebetween.

Optionally, the board body further comprises a third edge portion extending from the board body oppositely to the second edge portion in the vertical direction and beyond the first edge portion; the member further comprises a third receiving groove recessed into the top wall from the first channel and extending in the lateral direction; and at least a portion of the third edge portion is received in the third receiving groove.

Optionally, the member comprises a top wall and a bottom wall opposite to each other in the vertical direction, the bottom wall has an outer surface facing towards the surface of the first board; and the member further comprises a first protrusion protruding from the outer surface of the bottom wall in the vertical direction and placed on the surface of the first board to space the outer surface of the bottom wall apart from the surface of the first board.

Optionally, the member further comprises a first sidewall and a second sidewall opposite to each other in a longitudinal direction perpendicular to the vertical direction and the lateral direction, and each extending between the top wall and the bottom wall in the vertical direction; the member further comprises a second protrusion protruding outwardly from the first sidewall in the longitudinal direction, and a third protrusion protruding outwardly from the second sidewall in the longitudinal direction, the second protrusion and the third protrusion each comprise a mounting hole extending in the vertical direction, and the second protrusion and the third protrusion are offset from each other in the longitudinal direction; and the electronic system further comprises a fastener disposed in the mounting hole and connected to the first board so as to secure the member on the first board.

Optionally, the electronic system comprises a plurality of the first electrical connectors, the members of the plurality of the first electrical connectors are secured on the first board and arranged in a row in the longitudinal direction, so that the slots of the subassembly housings of the plurality of the first electrical connectors face towards one and the same direction; and the second protrusion of one member of every adjacent two members of the row and the third protrusion of the other member thereof are arranged adjacent to and offset from each other in the longitudinal direction, and a pitch between longitudinal center lines of the slots of every adjacent two first electrical connectors is 9.2 mm.

Optionally, the second mating ends of the plurality of conductive elements are arranged in two rows each extending in the vertical direction, the two rows are opposed to and spaced apart from each other in a longitudinal direction perpendicular to the vertical direction and the lateral direction, the first edge portion comprises two surfaces opposite to each other in the longitudinal direction, and the plurality of first contact pads are disposed on the two surfaces, the first edge portion is disposed between the two rows of the second mating ends so that each of the two surfaces faces towards a corresponding one of the two rows.

Optionally, the subassembly housing comprises a first face and a first arm portion and a second arm portion each extending from the first face in the lateral direction and spaced apart from each other in the vertical direction, the second mating ends of the plurality of conductive elements protrude from the first face and are disposed between the first arm portion and the second arm portion, the first edge portion are held by the first arm portion and the second arm portion therebetween.

Optionally, the subassembly housing further comprises a second face from which the slot is recessed into the subassembly housing in the lateral direction, the first mating ends of the plurality of conductive elements are curved into the slot and arranged in two rows each extending in the vertical direction, the two rows are opposed to and spaced apart from each other across the slot in a longitudinal direction perpendicular to the vertical direction and the lateral direction.

Optionally, the second mating end of each of the plurality of conductive elements is attached to a corresponding first contact pad.

Optionally, the plurality of first contact pads are aligned in the vertical direction on the first edge portion, and the plurality of second contact pads are aligned in the lateral direction on the second edge portion.

Optionally, the member is a metal shell.

Optionally, each of the plurality of first contact pads is electrically connected to a corresponding one of the plurality of second contact pads via a corresponding conductive structure of the second board.

These techniques may be used alone or in any suitable combination. The foregoing summary is disposed by way of illustration and is not intended to be limiting.

### BRIEF DESCRIPTION OF THE DRAWINGS

The accompanying drawings may not be drawn to scale. In the drawings, each identical or nearly identical component that is illustrated in various figures may be represented by a like numeral. For purposes of clarity, not every component may be labeled in every drawing. In the drawings:

FIG. 1 is an elevation view of an electronic system, according to some embodiments.

FIG. 2A is a top perspective view of an electrical connector of the electronic system of FIG. 1.

FIG. 2B is a bottom perspective view of the electrical connector of FIG. 2A.

FIG. 2C is a rear perspective view of the electrical connector of FIG. 2A.

FIG. 2D is another bottom perspective view of the electrical connector of FIG. 2A.

FIG. 2E is a front view of the electrical connector of FIG. 2A.

FIG. 3A is a partially exploded view of the electrical connector of FIG. 2A, showing a member, a connector subassembly, and a board.

FIG. 3B is another partially exploded view of the electrical connector of FIG. 2A.

FIG. 4A is a cross-sectional view of the electrical connector of FIG. 2A taken along the line marked “4A-4A” in FIG. 2A.

FIG. 4B is a cross-sectional view of the electrical connector of FIG. 2A taken along the line marked “4B-4B” in FIG. 2A.

FIG. 5A is a perspective view of the electrical connector of FIG. 2A, with the member hidden and showing the connector subassembly and the board.

FIG. 5B is another perspective view of the electrical connector of FIG. 5A.

FIG. 5C is a cross-sectional view taken along the line marked “5C-5C” in FIG. 5A.

FIG. 6A is a front perspective view of the connector subassembly shown in FIG. 3A.

FIG. 6B is another front perspective view of the connector subassembly of FIG. 6A.

FIG. 6C is a rear perspective view of the connector subassembly of FIG. 6A.

FIG. 6D is another rear perspective view of the connector subassembly of FIG. 6A.

FIG. 6E is a partially exploded view of the connector subassembly of FIG. 6A, showing a subassembly housing, a terminal assembly, and a locking member of the connector subassembly.

FIG. 7A is a perspective view of the subassembly housing shown in FIG. 6E.

FIG. 7B is an enlarged view of the area “7B” circled by the dashed box in FIG. 7A.

FIG. 8A is a perspective view of the terminal assembly shown in FIG. 6E.

FIG. 8B is another perspective view of the terminal assembly of FIG. 8A.

FIG. 9A is a rear perspective view of the member shown in FIG. 3A.

FIG. 9B is another rear perspective view of the member of FIG. 9A.

FIG. 9C is a front perspective view of the member of FIG. 9A.

FIG. 9D is a cross-sectional view of the member of FIG. 9A taken along the line marked “9D-9D” in FIG. 9A.

FIG. 10A is a perspective view of an electronic system comprising a plurality of the electrical connectors of FIG. 2A mounted on a same board.

FIG. 10B is a top view of the electronic system of FIG. 10A.

### DETAILED DESCRIPTION

The inventors have recognized and appreciated connector design techniques for reliable, compact orthogonal connectors. These techniques may enable connectors that fit in a tight space in a system while maintaining/improving mechanical strength, have sufficient heat dissipation, and satisfy physical requirements by industry standards, such as the Enterprise and Datacenter Standard Form Factor (EDSFF) standard (e.g., SFF-TA-1002). The inventors have recognized and appreciated that some systems do not have enough space for conventional EDSFF connectors. Simply resizing conventional EDSFF connectors to fit in the space would cause various issues such as blocking the cooling airflow, applying greater momentum at the connector/board interface, not satisfying physical requirements by the standard, etc.

According to aspects of the present disclosure, a connector may include a holder with first and second channels, a housing disposed in the first channel and comprising a slot, conductors held by the housing, and a board coupled to conductors. Each conductor may include a first mating end disposed in the slot of the housing, and a second mating end engaging contact pads at a first edge of the board.

The board may include a second edge aligned with an opening of the second channel. The second channel of the holder may be configured to facilitate heat dissipation and reduce connector weight. The second edge may include contact pads configured to mate with another component (e.g., another connector). By enabling airflow over the board or the surface of the motherboard, which may contain electronic components that generate heat, cooling efficiency can be improved.

In some embodiments, the holder may include threaded side protrusions for securely mounting to a mainboard. The side protrusions may be offset from each other so that the side protrusions of adjacent connectors may be substantially aligned in a mating direction, thereby saving system space.

In some embodiments, the holder may include a shelf inside the second channel configured for holding a portion of the board. Such a configuration may enhance mechanical strength of the connector.

Techniques described herein can enable electrical connectors that are taller, thinner, and lighter in weight with sufficient/improved mechanical strength while meeting the physical requirements of industry standards, such as the EDSFF standard (e.g., SFF-TA-1002). As a specific example, the slot can have a height of 26.5 mm (measured from a midpoint of the slot to the mainboard), compared with a height of 7.8 mm for a conventional design. Additionally, a center-to-center pitch between adjacent connectors may be 9.2 mm, reduced from 11 mm.

In some embodiments, an electrical connector may include a connector subassembly having a subassembly housing and a plurality of conductive elements held in the subassembly housing. Each conductive element may include a first mating end, a second mating end opposite to the first mating end, and an intermediate portion joining the first mating end and the second mating end. The subassembly housing may include a slot elongated in the vertical direction. The first mating ends of the conductive elements may be exposed in the slot. The electrical connector may also include a board. The board may include a first edge portion, a plurality of first contact pads aligned in a vertical direction, a second edge portion disposed beyond the first edge portion in the vertical direction, and a plurality of second contact pads aligned in the lateral direction on the second edge portion. The second mating end of each conductive element may be disposed on a corresponding first contact pad on the first edge portion.

Since the second edge portion of the board extends in the vertical direction and beyond the first edge portion, an assembly formed by the connector subassembly and the board can have a higher height in the vertical direction. Such an assembly is suitable for being assembled in a compact space in an electronic system, while enabling sufficient heat dissipation. Such an assembly can meet the space requirements and heat dissipation requirements in the electronic system. Such an assembly is particularly suitable to meet the physical requirements of EDSFF standards (e.g., SFF-TA-1002).

In some embodiments, the board is a first board. The electrical connector may include a member that may accommodate and hold the subassembly housing therein and may be configured to be mounted to a second board, such as a motherboard. The member may include a first channel and a second channel each extending in the lateral direction. The first channel and the second channel may be aligned in the vertical direction and at least partially separated from each other in the vertical direction. The subassembly housing may be accommodated and held within the first channel of the member. When the member is mounted to the second board, the vertical direction is perpendicular to a surface of the second board, and the second channel is disposed between the first channel (as well as the subassembly housing in the first channel) and the second board in the vertical direction. For example, the second channel may be disposed between the connector subassembly and the second board in the vertical direction.

With such a configuration, the electrical connector formed by the connector subassembly, the board, and the member can have a higher height in the vertical direction. Such an electrical connector is compact in the width direction and suitable for being assembled in a compact space in an electronic system, while enabling sufficient heat dissipation. Such an electrical connector meets the space requirements and heat dissipation requirements of the electronic system. Such an electrical connector is particularly suitable for meeting the physical requirements of the EDSFF standard (SFF-TA-1002).

In some electronic systems, a cooling fan may be disposed to allow air to flow through the boards and the electrical components of the electronic system. The second channel of the member of the electrical connector may be used as an air flow channel to allow air to pass therethrough. Since the air flow channel is disposed between the connector subassembly and the second board, the resistance of the electrical connector to air flow can be reduced, thereby improving the heat dissipation performance. Further, the weight of the member and the electrical connector can be reduced by the formation of the second channel. In addition, the member can support the connector subassembly and the first board reliably and securely above the second board, thereby improving the reliability of the connection of the electrical connector to the second board.

In some embodiments, the first edge portion of the first board may be disposed within the first channel. The second edge portion of the first board may be disposed outside of the member and aligned with an opening of the second channel. With such a configuration, the second channel can direct air flowing through the second channel to the second edge portion of the first board, e.g., to the mating parts between the first board and another electrical connector on the second board, so as to help evacuate heat generated at the mating parts. Such a configuration can improve the heat dissipation performance of the electronic system.

In some embodiments, an outer surface of the bottom wall of the member may face towards the surface of the second board when the member is mounted on the second board. In some embodiments, the member may include a first protrusion protruding from the outer surface of the bottom wall in the vertical direction and configured to be placed on the surface of the second board so as to space the outer surface of the bottom wall apart from the surface of the second board. With such a configuration, it is possible to reduce the space on the second board occupied by the member and to improve the heat dissipation performance of the electronic system.

In some embodiments, the member may include a first sidewall and a second sidewall opposite each other in a longitudinal direction perpendicular to the vertical direction and the lateral direction, and each extending between the top wall and the bottom wall in the vertical direction. In some embodiments, the member may include a second protrusion protruding outwardly from the first sidewall in the longitudinal direction, and a third protrusion protruding outwardly from the second sidewall in the longitudinal direction, the second protrusion and the third protrusion each include a mounting hole extending in the vertical direction for receiving a fastener used for securing the member to the second board. The second protrusion and the third protrusion may be arranged to be offset from each other in the longitudinal direction. With such a configuration, when a plurality of the electrical connectors are mounted on the second board, the protrusions of adjacent electrical connectors may be arranged to be offset from each other. In this way, the plurality of electrical connectors may be disposed on the second board at a higher density to realize a high-density and small-pitch connector layout.

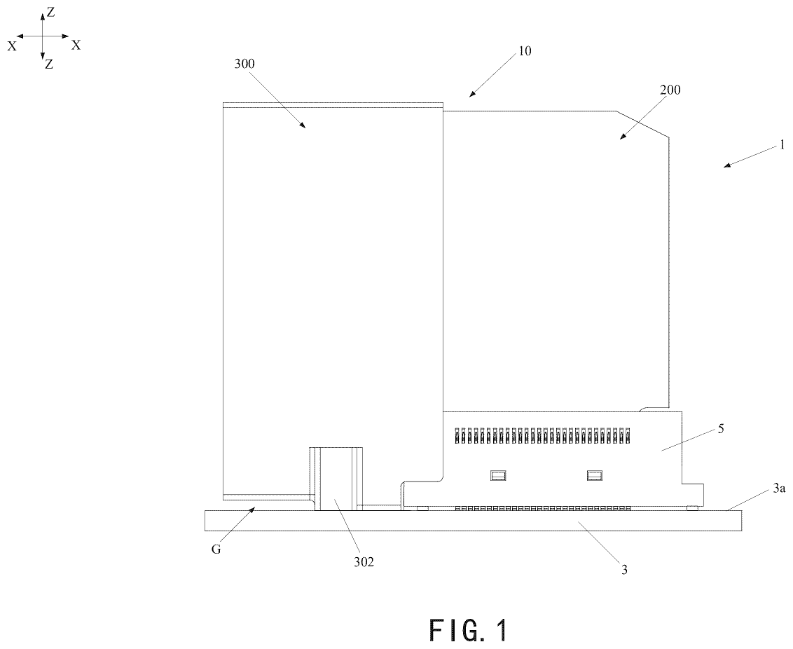

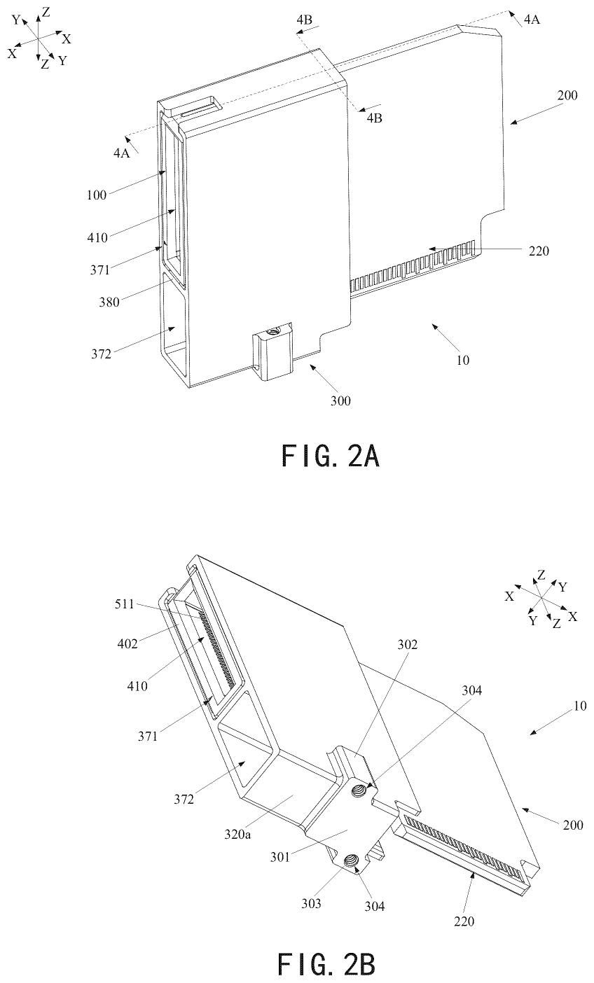

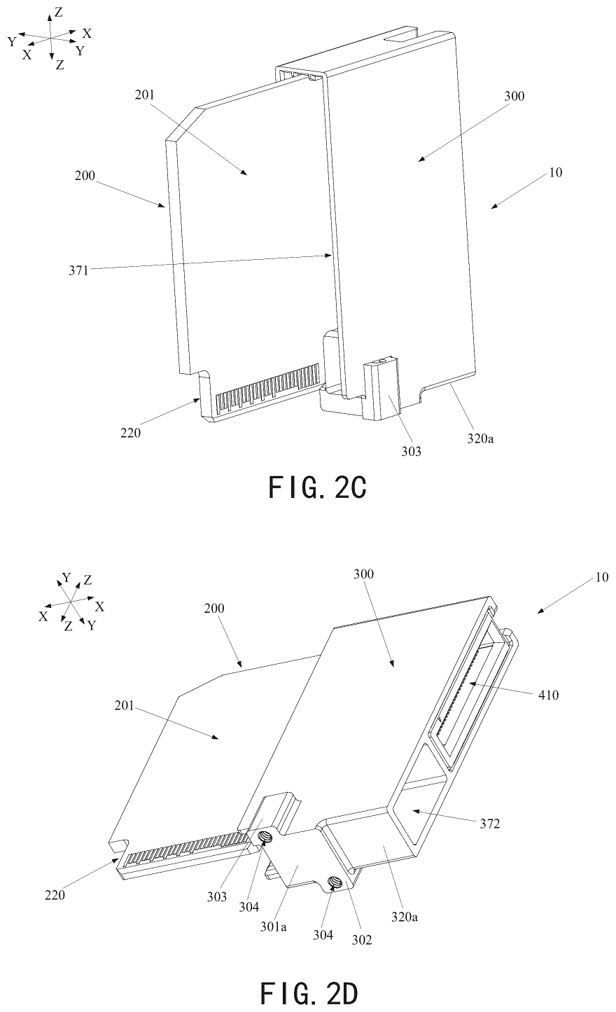

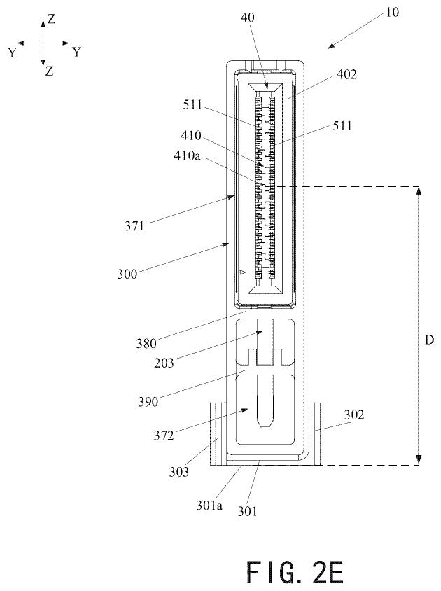

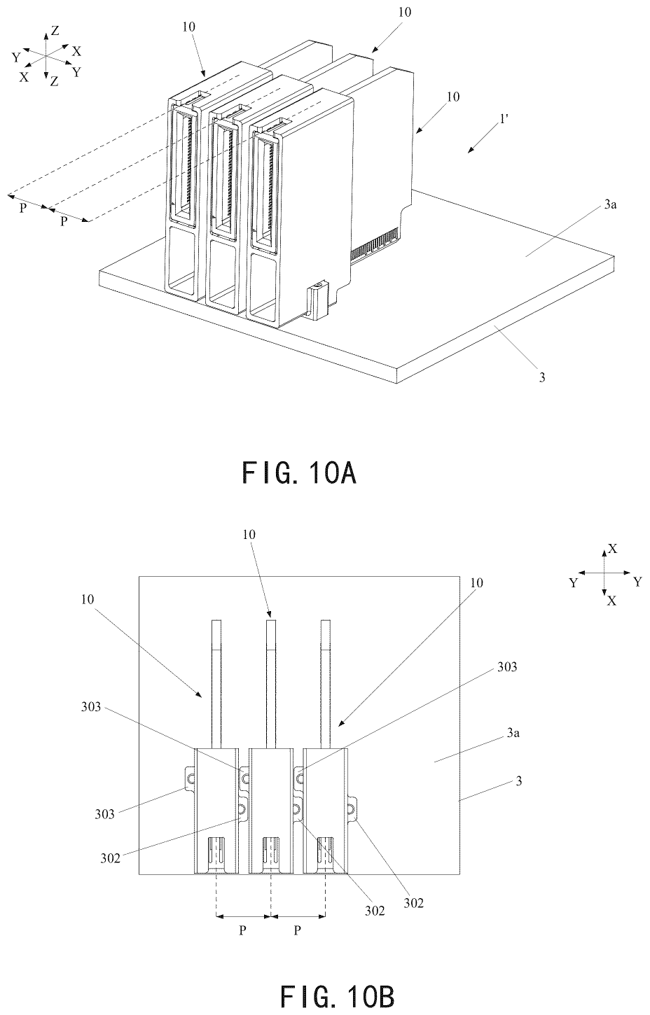

FIG. 1 illustrates an electronic system 1 including a board 3, an electrical connector 5, and an electrical connector 10, according to some embodiments of the present disclosure. FIG. 2A to 9D illustrate aspects of the electrical connector 10. FIGS. 10A to 10B illustrate an electronic system 1′ including a board 3 and a plurality of electrical connectors 10. For the sake of clarity and conciseness of description, a lateral direction X-X, a longitudinal direction Y-Y, and a vertical direction Z-Z may be defined in FIGS. 1 to 10B. The lateral direction X-X, the longitudinal direction Y-Y, and the vertical direction Z-Z may be perpendicular to each other. The lateral direction X-X may refer to a length direction of the electrical connector 10. The longitudinal direction Y-Y may refer to a width direction of the electrical connector 10. The vertical direction Z-Z may refer to a height direction of the electrical connector 10.

As shown in FIG. 1, the electronic system 1 may include the board 3, the electrical connector 5, and the electrical connector 10. The board 3 may be a motherboard of a server, a switch, or other computing device. The electrical connector 5 may be an on-board connector that is mounted on and connected to the board 3. The electrical connector 5 may be mechanically secured on the board 3 and electrically connected to a conductive structure (e.g., contact pads or conductive through-holes) of the board 3. The electrical connector 5 may provide an electrical interface for electrically connecting the electrical connector 10 to the board 3.

The electrical connector 10 may be configured to establish an electrical connection between the electrical connector 5 and an electrical component (not shown). The electrical component may, for example, be another board. For example, the other board may be an add-in card, such as a solid state drive (SSD), a network interface card (NIC), a graphics processing unit (GPU), etc. The electrical connector 10 may be secured on the board 3 (e.g., secured on a surface 3a of the board 3) and be mated with the electrical connector 5, so as to be electrically connected to the board 3 via the electrical connector 5. The other board, such as an add-in card, may be inserted into a slot of the electrical connector 10 to mate with the electrical connector 10. In this way, the other board may be electrically connected to the board 3 via the electrical connector 10 and the electrical connector 5 so as to enable signal and/or power transmission between the other board and the board 3. The other board and the board 3 may be orthogonal to each other. The electrical connector 10 may be referred to as “an orthogonal electrical connector”.

It should be appreciated that the present disclosure may not be limited thereto. In some embodiments, the electrical connector 10 may be configured to establish an electrical connection between the electrical connector 5 and another electrical connector, such as a plug connector, which may be mounted on another board or may be attached with a cable.

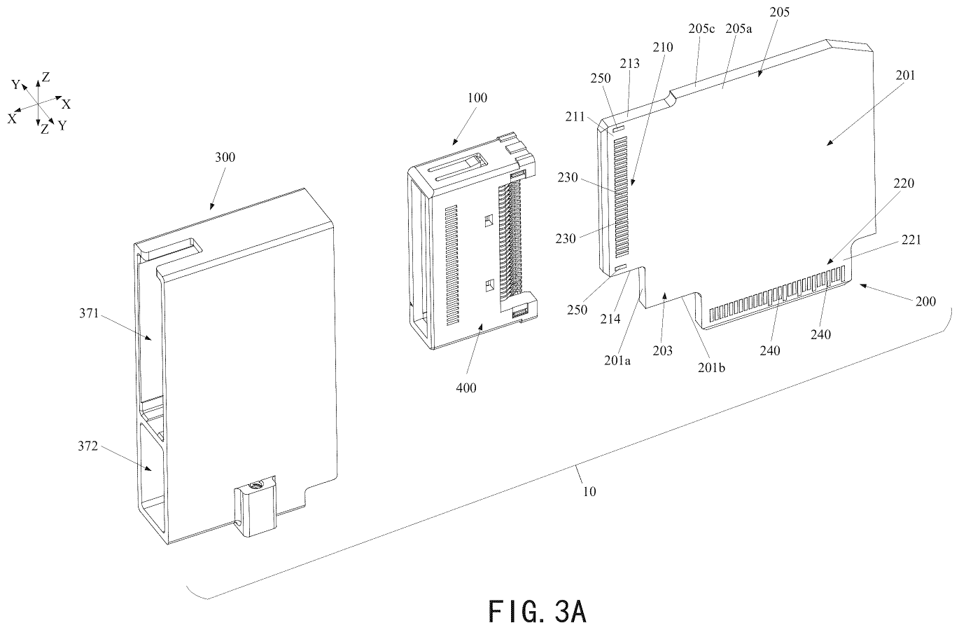

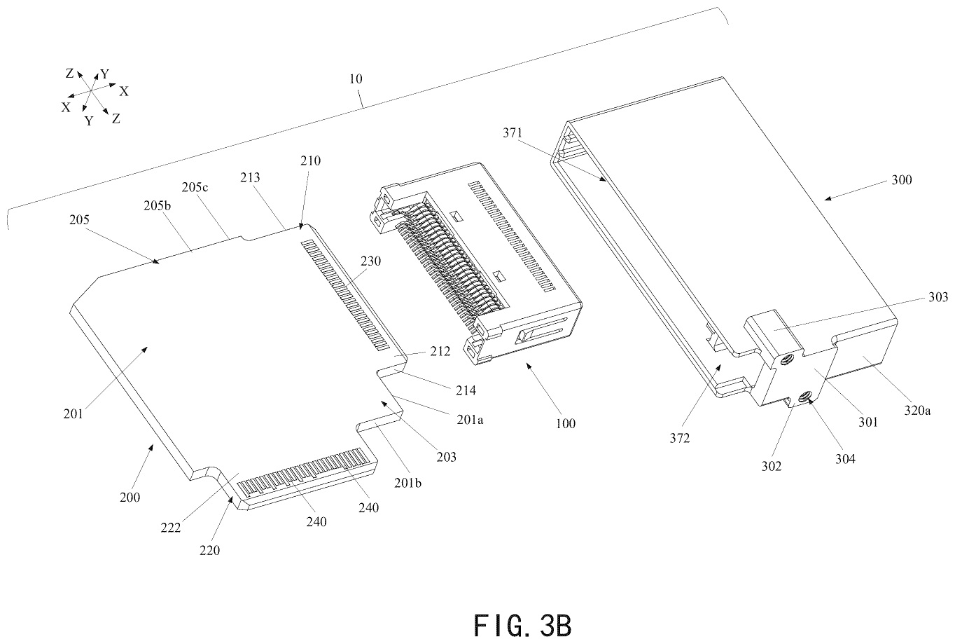

FIGS. 2A to 9D illustrate aspects of the electrical connector 10. As shown in FIGS. 3A and 3B, the electrical connector 10 may include a connector subassembly 100, a board 200, and a member 300. As shown in FIGS. 2A to 2E, the connector subassembly 100 and a portion of the board 200 may be accommodated and held in the member 300. The member 300 may be configured to be secured onto the surface 3a of the board 3, thereby holding the connector subassembly 100 and the board 200 to be fixed relative to the board 3.

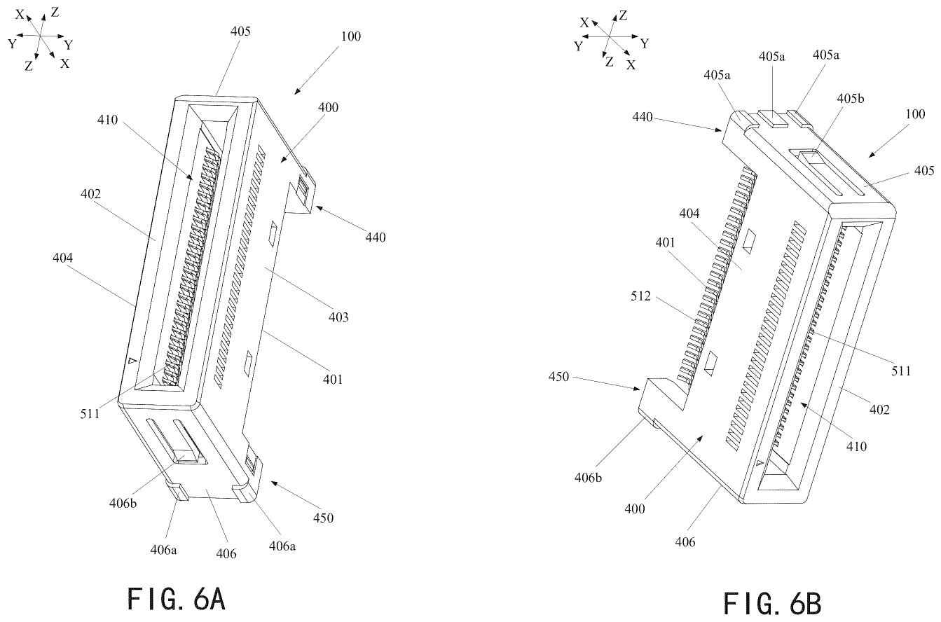

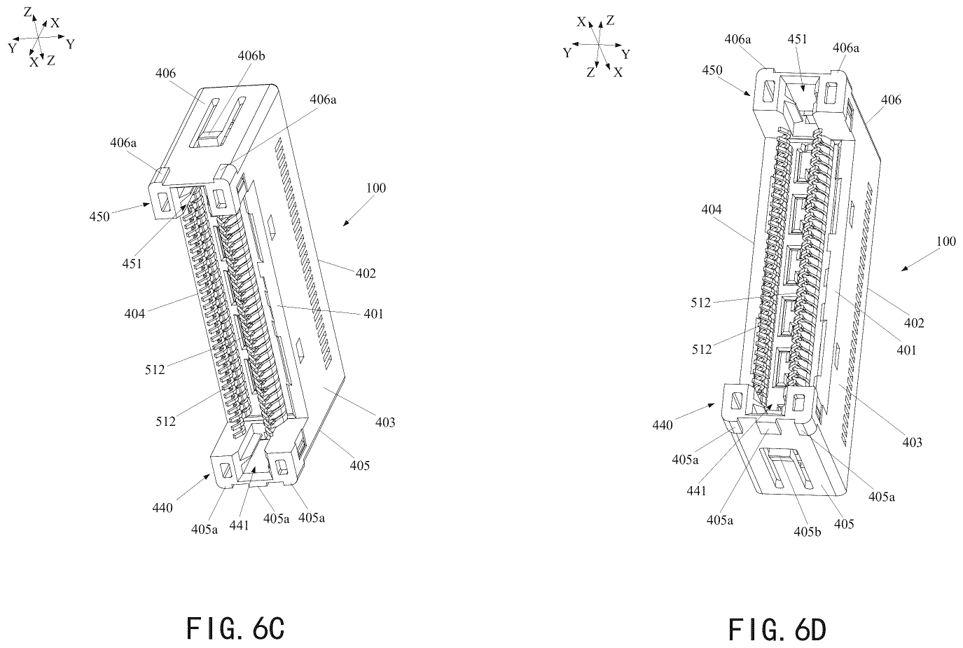

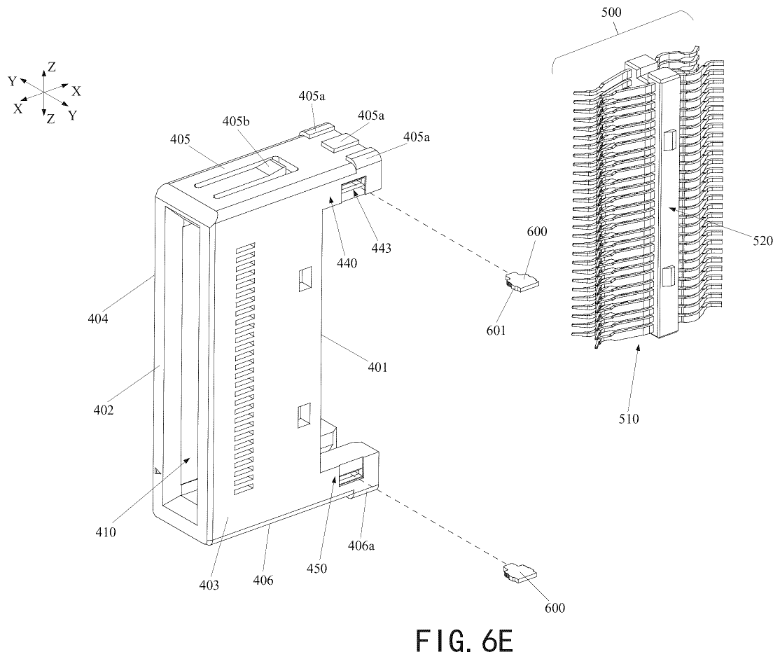

FIGS. 6A to 8B illustrate aspects of the connector subassembly 100. As shown in FIGS. 6A to 6E, the connector subassembly 100 may include a subassembly housing 400, a terminal assembly 500 disposed in the subassembly housing 400, and a locking member 600. The terminal assembly 500 may include a plurality of conductive elements 510 and a terminal housing 520. The subassembly housing 400 and the terminal housing 520 may each be formed from an insulative material. Examples of insulative materials suitable for manufacturing the subassembly housing 400 and the terminal housing 520 include, but are not limited to, plastic, nylon, liquid crystal polymer (LCP), polyphenylene sulfide (PPS), high temperature nylon or polyphenylene oxide (PPO) or polypropylene (PP). Each of the plurality of conductive elements 510 may be formed from a conductive material. The conductive material suitable for forming the conductive element 510 may be a metallic material, such as a copper or a copper alloy.

The subassembly housing 400 may include a first face 401 and a second face 402 opposite to each other in the lateral direction X-X, a third face 403 and a fourth face 404 opposite to each other in the longitudinal direction Y-Y, and a fifth face 405 and a sixth face 406 opposite to each other in the vertical direction Z-Z. The first face 401 may also be referred to as “a mounting surface”, the second face 402 may also be referred to as “a mating surface”, the third face 403 and fourth face 404 may also be referred to as “a first side face” and “a second side face”, respectively, and the fifth face 405 and the sixth face 406 may also be referred to as “a first end face” and “a second end face”, respectively.

As shown in FIGS. 6A, 6B and 6E, the subassembly housing 400 may include a slot 410 recessed into the subassembly housing 400 from the second face 402 in the lateral direction X-X. The slot 410 may be elongated in the vertical direction Z-Z. Another board, such as an add-in card, or a plug connector may be inserted into the slot 410 of the subassembly housing 400 to establish an electrical connection with the conductive elements 510 of the connector subassembly 100. The slot 410 is configured to receive an edge portion of the add-in card or an insert portion of the plug connector therein. Although the subassembly housing 400 is shown as including a single slot 410, it should be appreciated that the subassembly housing 400 may include more than one slot. For example, multiple slots may be spaced apart from each other in the vertical direction Z-Z.

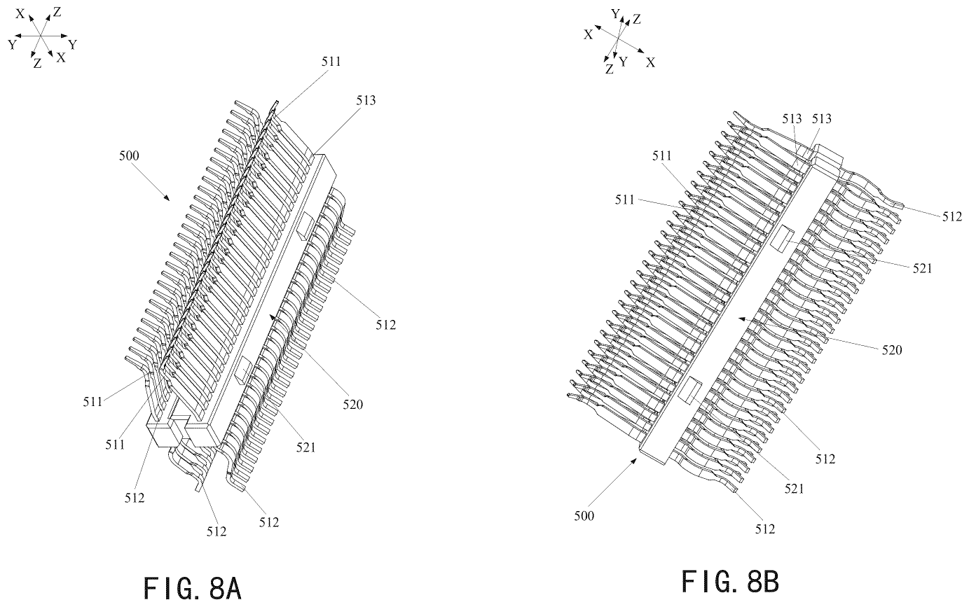

In some embodiments, as shown in FIGS. 6E, 8A, and 8B, the plurality of conductive elements 510 may be held in place relative to each other by the terminal housing 520 to form the terminal assembly 500. The terminal assembly 500 may be disposed in the subassembly housing 400 to hold the plurality of conductive elements 510 in the subassembly housing 400.

As illustrated in FIGS. 8A and 8B, each conductive element 510 includes a first mating end 511, a second mating end 512 opposite to the first mating end 511, and an intermediate portion 513 joining the first mating end 511 and the second mating end 512. The intermediate portion 513 extends between the first mating end 511 and the second mating end 512. Each conductive element 510 may provide a conductive path from the first mating end 511 to the second mating end 512 via the intermediate portion 513. The first mating end 511 may be configured to establish an electrical connection with a mating conductive structure (e.g., a contact pad or a conductive element) of another board, such as an add-in card, or another plug connector, and the second mating end 512 may be configured to establish an electrical connection with a mating conductive structure (e.g., a contact pad) on the board 200 of the electrical connector 10.

As shown in FIGS. 6E, 8A, and 8B, the intermediate portions 503 of the plurality of conductive elements 510 may be at least partially held by the terminal housing 520, so that the plurality of conductive elements 510 are held in place relative to each other by the terminal housing 520. For example, the terminal housing 520 may be molded around the intermediate portions 503 of the plurality of conductive elements 510, or the terminal housing 520 may be formed with terminal channels, and the intermediate portions 503 of the terminal housing 520 may be inserted and held in the terminal channels. The plurality of conductive elements 510 may be arranged in two terminal rows each extending in the vertical direction Z-Z, the two terminal rows are opposed to and spaced apart from each other in the longitudinal direction Y-Y. The conductive elements 510 of each terminal row are aligned with and spaced apart from each other in the vertical direction Z-Z. The terminal housing 520 may include a single piece or a plurality of pieces joined together.

As shown in FIGS. 8A and 8B, the first mating ends 511 of the plurality of conductive elements 510 may be arranged in two rows each extending in the vertical direction Z-Z, the two terminal rows are opposed to and spaced apart from each other in the longitudinal direction Y-Y. The first mating ends 511 of each row are aligned with and spaced apart from each other in the vertical direction Z-Z. Further, as shown in FIGS. 8A and 8B, the second mating ends 512 of the plurality of conductive elements 510 may be arranged in two rows each extending in the vertical direction Z-Z, the two terminal rows are opposed to and spaced apart from each other in the longitudinal direction Y-Y. The second mating ends 512 of each row are aligned with and spaced apart from each other in the vertical direction Z-Z.

The plurality of conductive elements 510 may be configured for transmitting power and/or signals. For example, each terminal row may include pairs of signal terminals and ground terminals that separate adjacent pairs of the pairs of signal terminals from each other. The pairs of signal terminals may be configured as differential signal pairs for transmitting differential signals. As illustrated, one signal terminal of a pair of signal terminals may be energized by a first voltage, and the other signal terminal may be energized by a second voltage. The voltage difference between the pair of signal terminals represents a signal. As another example, the plurality of conductive elements 510 may include power terminals configured for transmitting power. The signal terminals, the ground terminals, and the power terminals may have substantially the same configurations. It should be appreciated, however, that the present disclosure is not limited to the configuration of the conductive elements 510 shown in the drawings. The plurality of conductive elements 510 of the electrical connector 10 may have any suitable configuration to achieve transmission of power and/or signals.

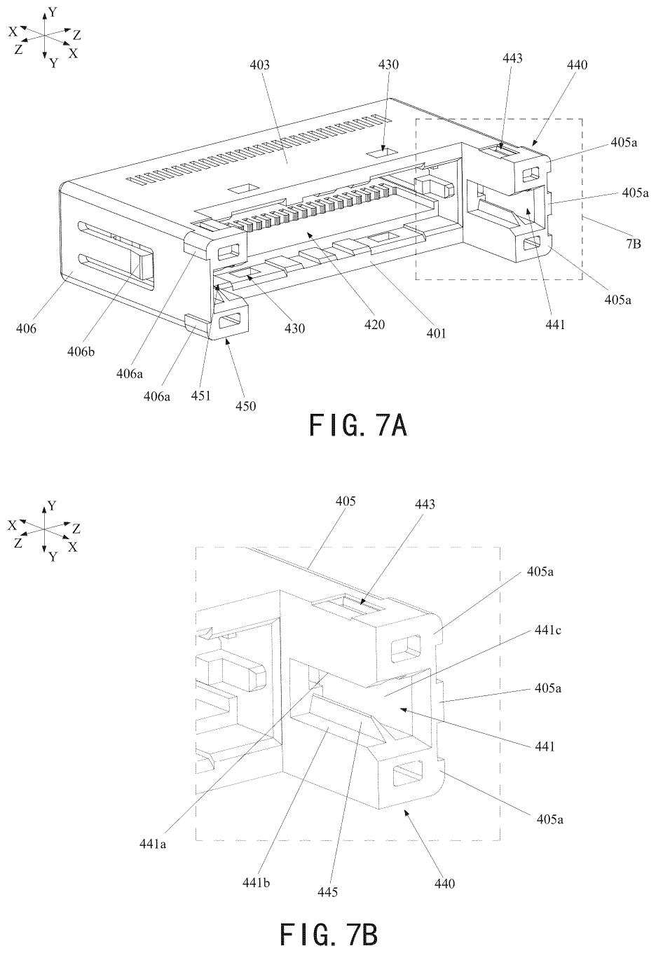

As shown in FIG. 7A, the subassembly housing 400 may include a space 420 recessed into the subassembly housing 400 from the first face 401 in the lateral direction X-X. The space 420 may be in communication with the slot 410. The terminal assembly 500 may be inserted and held in the space 420, and the first mating ends 511 of the plurality of conductive elements 510 may be disposed in the slot 410. The subassembly housing 400 may include a recess 430 recessed into the subassembly housing 400 from the space 420 in the longitudinal direction Y-Y. The terminal housing 520 may include a projection 521. When the terminal assembly 500 is inserted into the space 420 of the subassembly housing 400, the projection 521 engages with the recess 430 so that the terminal assembly 500 is held in the space 420. It should be appreciated that the present disclosure may not be limited thereto. The terminal assembly 500 may be held in the subassembly housing 400 by any suitable means or mechanism.

As shown in FIGS. 6A and 6B, when the terminal assembly 500 is disposed in the subassembly housing 400, the first mating ends 511 of the plurality of conductive elements 510 may be curved into the slot 410 and arranged in two rows as described above and each extending in the vertical direction Z-Z. The two rows of the first mating ends 511 are opposed to and spaced apart from each other across the slot 410 in the longitudinal direction Y-Y. As an example, an edge portion of another board, such as an add-in card, may be inserted into the slot 410 and disposed between the two rows of the first mating ends 511, so that mating contact pads on the edge portion contact with the first mating ends 511 of the plurality of conductive elements 510. In this way, a separable electrical connection can be established between the connector subassembly 100 and the other board. As another example, an insert portion of the plug connector may be inserted into the slot 410 and disposed between two rows of the first mating ends 511, so that mating ends of mating conductive elements on the insert portion contact with the first mating ends 511 of the plurality of conductive elements 510. In this way, a separable electrical connection can be established between the connector subassembly 100 and the plug connector. Although the subassembly housing 400 is shown as including a single slot 410 and the first mating ends 511 of the conductive elements 510 are all disposed in the slot 410, it should be appreciated that the subassembly housing 400 may include a plurality of slots, and the first mating ends 511 of the plurality of conductive elements 510 may each be disposed in a corresponding one of the plurality of slots.

As shown in FIGS. 6C and 6D, when the terminal assembly 500 is disposed in the subassembly housing 400, the second mating ends 512 of the plurality of conductive elements 510 may extend out of the first face 401 and be arranged in two rows as described above and each extending in the vertical direction Z-Z. The two rows of the second mating ends 512 are opposed to and spaced apart from each other in the longitudinal direction Y-Y.

FIGS. 3A and 3B illustrate aspects of the board 200. The board 200 may also be referred to as “a printed circuit board (PCB)”. As shown in FIGS. 3A and 3B, the board 200 may include a first edge portion 210, a plurality of first contact pads 230 aligned in the vertical direction Z-Z on the first edge portion 210, a second edge portion 220 disposed beyond the first edge portion 210 in the vertical direction Z-Z, and a plurality of second contact pads 240 aligned in the lateral direction X-X on the second edge portion 220. For example the first edge portion 210 and the second edge portion 220 extend in orthogonal directions. The first edge portion 210 may be elongated in the vertical direction Z-Z, and the second edge portion 220 may be elongated in the lateral direction X-X. Each of the plurality of first contact pads 230 may be electrically connected to a corresponding one of the plurality of second contact pads 240 via a corresponding conductive structure of the board 200, such as a conductive trace or a conductive layer.

The first contact pads 230 may be configured to establish an electrical connection with the second mating end 512 of the corresponding conductive element 510 of the connector subassembly 100. The first edge portion 210 includes a first surface 211 and a second surface 212 opposite to each other in the longitudinal direction Y-Y, and the plurality of first contact pads 230 are disposed on the first surface 211 and the second surface 212. As illustrated, a first portion of the plurality of first contact pads 230 are disposed on the first surface 211 and aligned in the vertical direction Z-Z. A second portion of the plurality of first contact pads 230 are disposed on the second surface 212 and aligned in the vertical direction Z-Z. It should be appreciated that the present disclosure may not be limited thereto. For example, the first edge portion 210 may have the first contact pads on only one of the surfaces.

The second edge portion 220 is configured to be inserted into the electrical connector 5 mounted on the board 3, so that each of the plurality of second contact pads 240 mates with a corresponding conductive element of the electrical connector 5 to establish an electrical connection between the board 200 and the electrical connector 5. The second edge portion 220 may be referred to as “an insert portion” of the board 200. The second edge portion 220 includes a first surface 221 and a second surface 222 opposite to each other in the longitudinal direction Y-Y, and the plurality of second contact pads 240 are disposed on the first surface 221 and the second surface 222. As illustrated, a first portion of the plurality of second contact pads 240 are disposed on the first surface 221 and arranged in the vertical direction Z-Z. A second portion of the plurality of second contact pads 240 are disposed on the second surface 222 and arranged in the vertical direction Z-Z. It should be appreciated that the present disclosure may not be limited thereto. The second edge portion 220 may have the second contact pads on only one of the surfaces.

It should be appreciated that the first contact pads 230 and the second contact pads 240 are not limited to being in the rectangular shape as shown, but may be in any suitable shape. It should also be appreciated that although the first contact pads 230 and the second contact pads 240 are shown as separate contact pads, in some embodiments, the first contact pads 230 and/or the second contact pads 240 may be continuous conductive areas. For example, the first mating ends 511 of the plurality of conductive elements 510 may be connected to one and the same first contact pad 230, and/or a plurality of conductive elements of the electrical connector 5 may be connected to one and the same second contact pad 240.

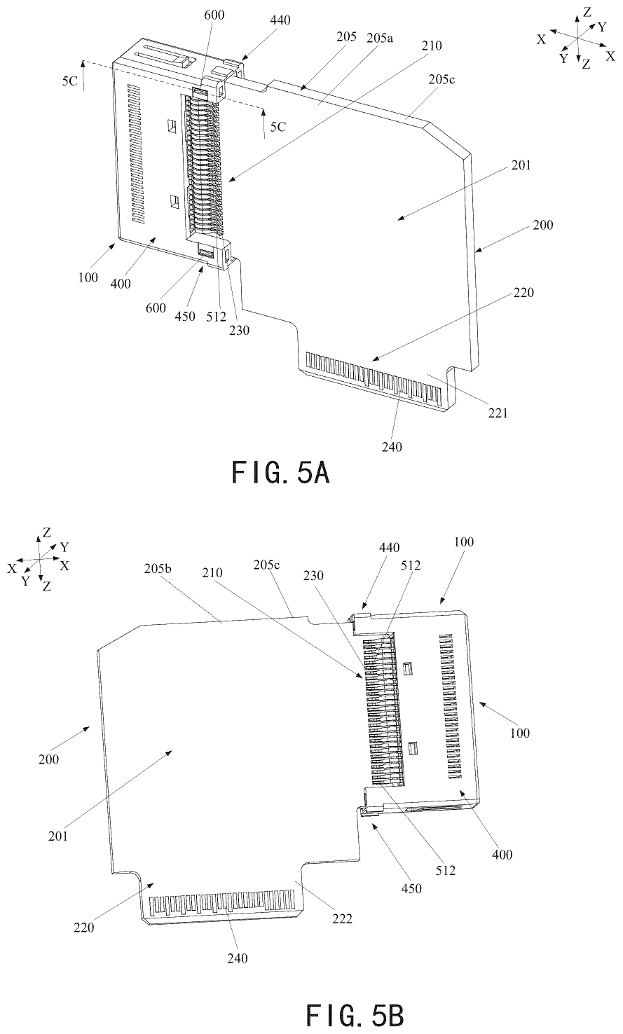

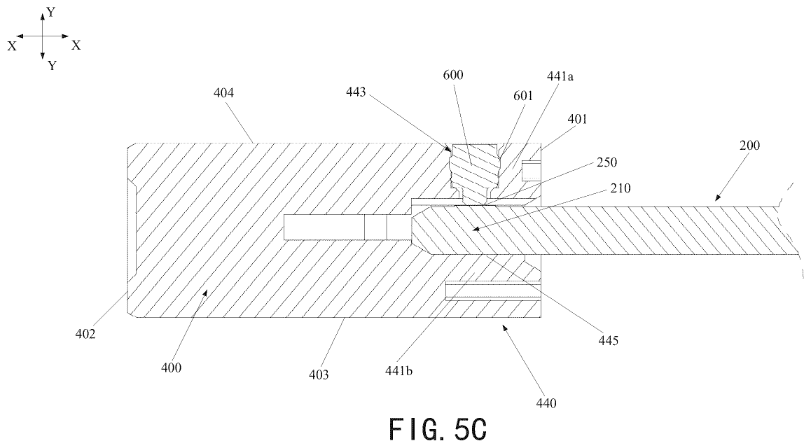

The board 200 may be connected to the connector subassembly 100. The board 200 may be fixedly disposed relative to the subassembly housing 400. In some embodiments, the subassembly housing 400 may be secured on the first edge portion 210 of the board 200. As shown in FIGS. 5A and 5B, the second mating end 512 of each of the plurality of conductive elements 510 may be disposed on and in contact with a corresponding one of the plurality of first contact pads 230 on the first edge portion 210 of the board 200. In this way, an electrical connection can be established between the connector subassembly 100 and the board 200. As illustrated, the second edge portion 220 of the board 200 extends in the vertical direction Z-Z and beyond the first edge portion 210, so that the connector 10 formed by the connector subassembly 100 and the board 200 can have a higher height in the vertical direction Z-Z. Such an assembly is suitable for being assembled in a compact space in an electronic system, while enabling sufficient heat dissipation. For example, such an assembly can meet space requirements and heat dissipation requirements in the electronic system. Such an assembly is especially suitable to meet the physical requirements of the EDSFF standard (e.g., SFF-TA-1002).

As shown in FIGS. 5A and 5B, the first edge portion 210 of the board 200 is disposed between the two rows of the second mating ends 512 of the conductive elements 510, so that each of the first surface 221 and the second surface 222 of the first edge portion 210 faces towards a corresponding one of the two rows. Each second mating end 512 is disposed on and in contact with a corresponding first contact pad 230. For each conductive element 510, the second mating end 512 may extend curvedly from the intermediate portion 513 to press against the corresponding first contact pad 230. In some embodiments, as shown in FIGS. 5A and 5B, for each conductive element 510, the second mating end 512 may be attached (e.g., by a surface mounting technique) to the corresponding first contact pad 230. In some embodiments, for each conductive element 510, the second mating end 512 may be resiliently pressed against the corresponding first contact pad 230, so that by a resilient pressure only, contact is maintained between the second mating end 512 and the corresponding first contact pad 230.

In some embodiments, as shown in FIGS. 5A and 5B, the subassembly housing 400 may include a first arm portion 440 and a second arm portion 450 to receive and hold the first edge portion 210 of the board 200. The first arm portion 440 and the second arm portion 450 extend from the first face 401 in the lateral direction X-X, respectively, and are spaced apart from each other in the vertical direction Z-Z. As shown in FIGS. 6C to 6D, the second mating ends 512 of the plurality of conductive elements 510 may extend from the first face 401 and be disposed between the first arm portion 440 and the second arm portion 450. As shown in FIGS. 6C to 6D and 7A to 7B, the first arm portion 440 may include a first groove 441, and the second arm portion 450 may include a second groove 451. The first groove 441 is recessed into the first arm portion 440 in the vertical direction Z-Z and extends in the lateral direction X-X. The second groove 451 is recessed into the second arm portion 450 in the vertical direction Z-Z and extends in the lateral direction X-X. The first groove 441 and the second groove 451 may be arranged to be opposed to each other in the vertical direction Z-Z. The first edge portion 210 of the board 200 is inserted between the first arm portion 440 and the second arm portion 450, so that a first end 213 and a second end 214 of the first edge portion 210, which are opposite to each other in the vertical direction Z-Z (FIGS. 3A and 3B), are received in the first groove 441 and the second groove 451, respectively, so that the first arm portion 440 and the second arm portion 450 hold the first edge portion 210 therebetween. In this way, the board 200 may be fixedly disposed relative to the subassembly housing 400. For example, the subassembly housing 400 may be mounted on the first edge portion 210 of the board 200. The first face 401 of the subassembly housing 400 faces towards an edge of the first edge portion 210 of the board 200.

As illustrated in FIG. 7B, the first groove 441 of the first arm portion 440 includes a first wall 441a and a second wall 441b facing towards each other in the longitudinal direction Y-Y, and a bottom wall 441c extending between the first wall 441a and the second wall 441b. In some embodiments, as shown in FIG. 7B, the first arm portion 440 may include a passage 443 extending from an outer side of the first wall 441a through the first wall 441a into the first groove 441 in the longitudinal direction Y-Y. The locking member 600 may be inserted in the passage 443 of the first arm portion 440 and extend into the first groove 441 to engage with the first edge portion 210, so as to hold the first edge portion 210 relative to the subassembly housing 400. The engagement of the locking member 600 with the first edge portion 210 may at least restrict the movement of the first edge portion 210 relative to the subassembly housing 400 in the lateral direction X-X. With such a configuration, the board 200 can be reliably held in place relative to the subassembly housing 400. In some embodiments, as shown in FIGS. 5C and 6E, the locking member 600 may include a barb feature 601 to enhance the engagement with an inner wall of the passage 443.

In some embodiments, as shown in FIGS. 3A and 5C, the board 200 may include a locking pad 250 disposed on the first edge portion 210. As illustrated in FIG. 5C, the locking pad 250 faces towards the passage 443 of the first arm portion 440 and is aligned with the passage 443. The locking member 600 engages the locking pad 250 (e.g., by soldering, welding, etc.) to hold the first edge portion 210 relative to the subassembly housing 400. With such a configuration, the reliability of the connection of the board 200 to the connector subassembly 100 can be improved. For example, a reflow technique may be utilized in one and the same process to engage the second mating ends 512 of the conductive elements 510 with the corresponding first contact pads 230 of the first edge portion 210 and, at the same time, engage the locking member 600 with the locking pad 250. With such a configuration, the efficiency of assembling the board 200 with the connector subassembly 100 can be improved.

It should be appreciated that the present disclosure may not be limited thereto. The locking member 600 may engage with any other suitable structure of the first edge portion 210 to hold the first edge portion 210 relative to the subassembly housing 400. For example, in some embodiments, the first edge portion 210 may include an insert hole (not shown), and a portion of the locking member 600 may be inserted into the insert hole to hold the first edge portion 210 relative to the subassembly housing 400.

In some embodiments, as shown in FIG. 7B, the first arm portion 440 may include a projection 445 protruding from the second wall 441b of the first groove 441 into the first groove 441 in the longitudinal direction Y-Y. The projection 445 may be in the form of a rib and extend in the lateral direction X-X. The first wall 441a may be planar. As shown in FIG. 5C, the protrusion 445 and the first wall 441a may sandwich the first end 213 of the first edge portion 210 therebetween. The protrusion 445 and the first wall 441a can restrict the movement of the first end 213 of the first edge portion 210 in the longitudinal direction Y-Y. In this way, the first end 213 of the first edge portion 210 can be firmly held in the first groove 441.

As shown in FIGS. 6C, 6D, and 7A, the configuration of the second arm portion 450 may be similar to that of the first arm portion 440. Another locking member 600 may be disposed in the second arm portion 450 in a similar manner so as to engage with the first edge portion 210, thereby holding the first edge portion 210 relative to the subassembly housing 400. For brevity, details of identical portions may not be repeated. It should be appreciated that each of the first groove 441 of the first arm portion 440 and the second groove 451 of the second arm portion 450 may include a first wall and a second wall facing towards each other in the longitudinal direction Y-Y, and that each of the first arm portion 440 and the second arm portion 450 further includes a passage extending from an outer side of the corresponding first wall through the first wall into the corresponding groove in the longitudinal direction Y-Y. The locking member 600 may be inserted in the passage of the corresponding arm portion and extend into the corresponding groove to engage with the first edge portion 210, thereby retaining the first edge portion 210 relative to the subassembly housing 400. Each of the first groove 441 of the first arm portion 440 and the second groove 451 of the second arm portion 450 may further include a projection extending from the corresponding second wall into the groove in the longitudinal direction Y-Y. The protrusion and the first wall sandwich a corresponding one of the first end 213 and the second end 214 of the first edge portion 210 therebetween. In this way, it is possible to restrict the movement of the first edge portion 210 relative to the subassembly housing 400 in the longitudinal direction Y-Y. Each of the locking pads 250 on the first edge portion 210 may face towards the passage of a corresponding one of the first arm portion 440 and the second arm portion 450 and be aligned with the passage, and the corresponding locking member 600 may be attached to the locking pad 250. When the first edge portion 210 is held by the first arm portion 440 and the second arm portion 450 therebetween, the first end 213 of the first edge portion 210 may engage with a bottom wall 441c of the first groove 441 and the second end 214 may engage with a bottom wall (not labeled) of the second groove 451, so as to restrict the movement of the first edge portion 210 relative to the subassembly housing 400 in the vertical direction Z-Z.

Although it is described above that the plurality of conductive elements 510 are held in place relative to each other by the terminal housing 520 to form the terminal assembly 500, and that the terminal assembly 500 is disposed in the subassembly housing 400 to hold the plurality of conductive elements 510 in the subassembly housing 400, it should be appreciated that the present disclosure is not limited to thereto. In some embodiments, the plurality of conductive elements 510 may be disposed and held in the subassembly housing 400 in any other manner. For example, the subassembly housing 400 may be molded directly around the plurality of conductive elements 510, or the plurality of conductive elements 510 may be inserted directly into terminal channels formed in the subassembly housing 400.

Although the first edge portion 210 of the board 200 is described above as being held in place by the first arm portion 440 and the second arm portion 450 of the subassembly housing 400, it should be appreciated that the board 200 may be mechanically coupled to the subassembly housing 400 in any other suitable manner. Further, in some embodiments, the board 200 may be held in place by the member 300 relative to the subassembly housing 400.

Although the second mating ends 512 of the plurality of conductive elements 510 are described above as protruding from the first face 401, it should be appreciated that the second mating ends 512 of the plurality of conductive elements 510 may be disposed within the subassembly housing 400. For example, the subassembly housing 400 may include a slot recessed into the subassembly housing 400 from the first face 401 in the lateral direction X-X, and the second mating ends 512 of the plurality of conductive elements 510 may be curved into the slot and arranged in two rows each extending in the vertical direction Z-Z. The two rows of the second mating ends 512 are opposed to and spaced apart from each other across the slot in the longitudinal direction Y-Y. In this case, the first edge portion 210 of the board 200 may be inserted into the slot and disposed between the two rows of the second mating ends 512. The second mating end 512 of each conductive element 510 may be in electrical contact with a corresponding first contact pad 230.

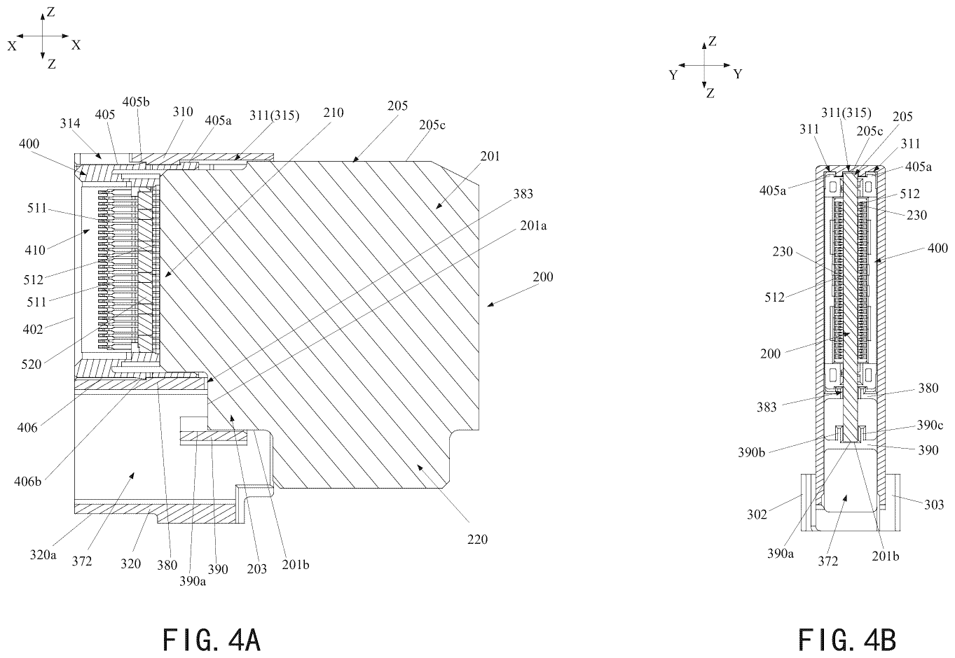

As shown in FIGS. 2A to 2E and 4A to 4B, the member 300 may accommodate and hold the subassembly housing 400 of the connector subassembly 100 therein. Accordingly, the conductive elements 510 of the connector subassembly 100 are also held in the member 300. As shown in FIG. 1, the member 300 may be secured onto the board 3. As described above, the board 200 is fixedly disposed relative to the subassembly housing 400. Thus, the member 300 may hold the connector subassembly 100 (which includes the subassembly housing 400 and the conductive elements 510) and the board 200 to be fixed relative to the board 3. The vertical direction Z-Z is perpendicular to the surface 3a of the board 3 when the member 300 is mounted onto the board 3. For example the electrical connector 10 is secured on the board 3 in an orientation in which the vertical direction Z-Z is perpendicular to the surface 3a of the board 3. The elongated direction of the slot 410 of the subassembly housing 400 is also perpendicular to the surface 3a of the board 3.

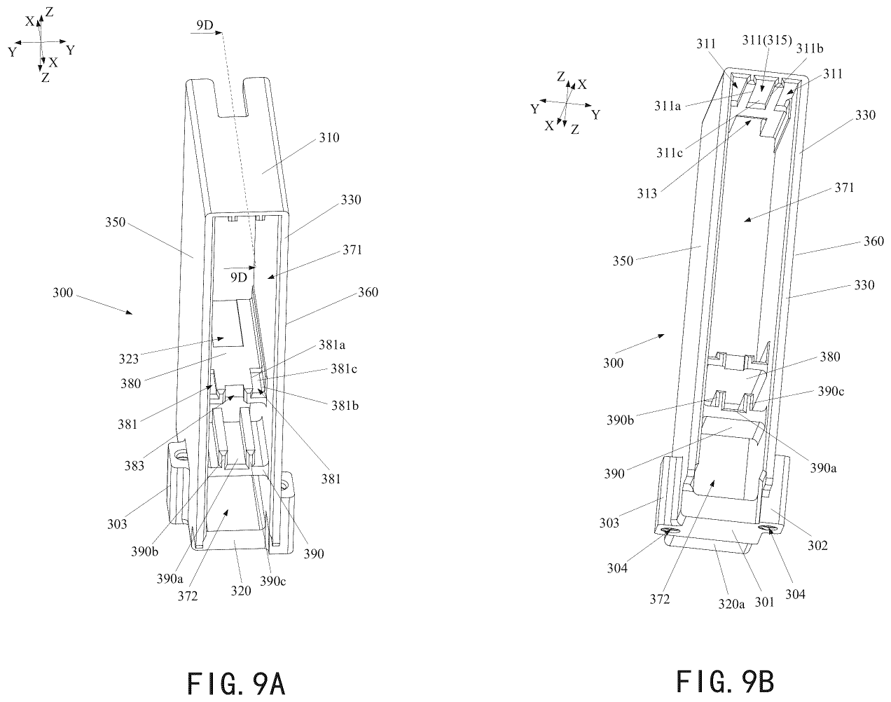

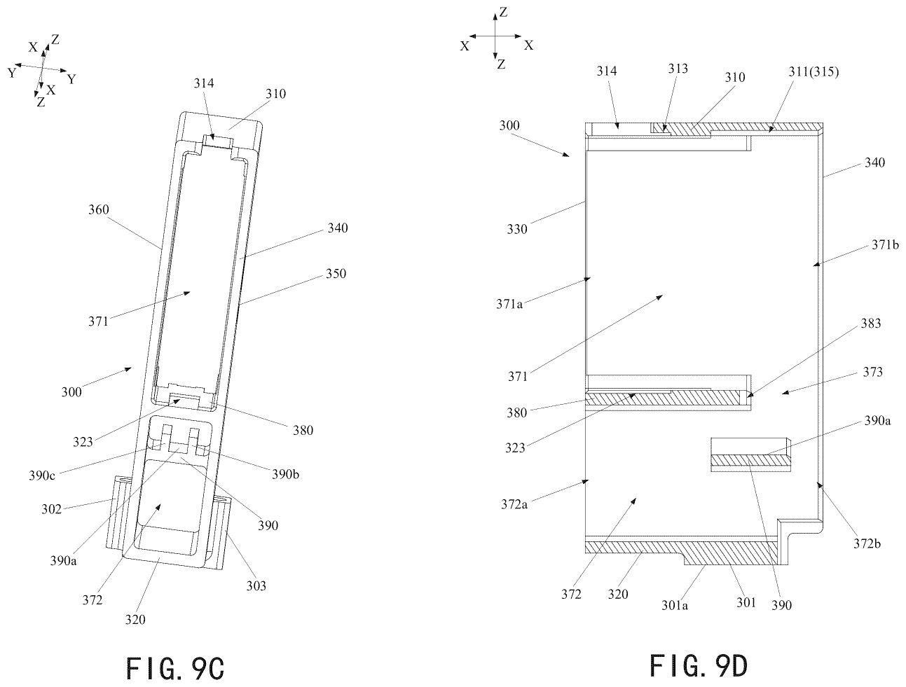

FIGS. 9A to 9D illustrate aspects of the member 300. The member 300 may also be referred to as “a holder” or “a shell”. As shown in FIGS. 9A to 9D, the member 300 may include a top wall 310 and a bottom wall 320 opposite to each other in the vertical direction Z-Z, a first side face 330 and a second side face 340 opposite to each other in the lateral direction X-X, and a first sidewall 350 and a second sidewall 360 opposite to each other in the longitudinal direction Y-Y. Each of the first sidewall 350 and the second sidewall 360 extends between the top wall 310 and the bottom wall 320 in the vertical direction Z-Z. In some embodiments, the member 300 may be formed from a metallic material. For example, the member 300 may be a metal shell.

The member 300 may include a first channel 371 and a second channel 372 each extending in the lateral direction X-X. Each of the first channel 371 and the second channel 372 may extend from the first side face 330 through the member 300 to the second side face 340 in the lateral direction X-X. As shown in FIG. 9D, the first channel 371 may include a first opening 371a at the first side face 330 and a second opening 371b at the second side face 340. The second channel 372 may include a third opening 372a at the first side face 330 and a fourth opening 372b at the second side face 340. The first channel 371 and the second channel 372 are aligned in the vertical direction Z-Z and are at least partially separated from each other in the vertical direction Z-Z.

The subassembly housing 400 may be accommodated and held within the first channel 371 of the member 300. When the member 300 is mounted onto the board 3, the second channel 372 is disposed between the first channel 371 and the board 3 in the vertical direction Z-Z. With such a configuration, the electrical connector 10 formed by the connector subassembly 100, the board 200, and the member 300 may have a higher height in the vertical direction Z-Z. The electrical connector 10 is compact and suitable for being assembled in a compact space in an electronic system, while enabling sufficient heat dissipation. For example, the electrical connector 10 can meet space requirements and heat dissipation requirements in the electronic system. The electrical connector 10 is especially suitable for meeting the physical requirements of the EDSFF standard (SFF-TA-1002). In some electronic systems, a cooling fan may be disposed to allow air to flow through boards and electrical components of the electronic systems. The second channel 372 may be used as an air flow channel to allow air to pass therethrough. As the air flow channel is disposed between the connector subassembly 100 and the board 3, the resistance of the electrical connector 10 to air flow is reduced, thereby improving the heat dissipation performance. Furthermore, the weight of the member 300 and the electrical connector 10 can be reduced due to the formation of the second channel 372. In addition, the member 300 can reliably and securely support the connector subassembly 100 and the board 200 above the board 3, thereby improving the reliability of the connection of the electrical connector 10 to the board 3.

When the member 300 is mounted onto the board 3, the bottom wall 320 of the member 300 is closer to the surface 3a of the board 3 than the top wall 310 in the vertical direction Z-Z. The member 300 may include a separation wall 380 disposed between the top wall 310 and the bottom wall 320 in the vertical direction Z-Z. The separation wall 380 at least partially separates the first channel 371 and the second channel 372 from each other. The first channel 371 is disposed between the top wall 310 and the separation wall 380, and the second channel 372 is disposed between the separation wall 380 and the bottom wall 320.

In some embodiments, as shown in FIG. 4A, the subassembly housing 400 may be held within the first channel 371 by the top wall 310 and the separation wall 380 of the member 300. As illustrated, as shown in FIGS. 6A to 6D, the subassembly housing 400 may include a first projection 405a protruding from the fifth face 405 in the vertical direction Z-Z and a second projection 406a protruding from the sixth face 406 in the vertical direction Z-Z. Although three first projections 405a and two second projections 406a are shown in the drawings, it should be appreciated that the number of the first projection 405a and the second projection 406a may not be limited thereto. The subassembly housing 400 may include at least one first projection 405a and at least one second projection 406a. As shown in FIGS. 9B and 9D, the member 300 may include a first receiving groove 311 recessed into the top wall 310 from the first channel 371 in the vertical direction Z-Z and extending in the lateral direction X-X. The number of the first receiving groove 311 corresponds to that of first projection 405a of the subassembly housing 400. As shown in FIGS. 9B and 9D, the member 300 may have a second receiving groove 381 recessed from the first channel 371 into the separation wall 380 in the vertical direction Z-Z and extending in the lateral direction X-X. The number of the second receiving groove 381 corresponds to that of the second projection 406a of the subassembly housing 400.

The subassembly housing 400 may be inserted into the first channel 371 from the second opening 371b of the first channel 371 in the lateral direction X-X. The first projection 405a is received in a corresponding first receiving groove 311 and engages with an end of the corresponding first receiving groove 311 (see, e.g., FIG. 4A), and the second projection 406a is received in a corresponding second receiving groove 381 and engages with an end of the corresponding second receiving groove 381, so as to restrict the further insertion of the subassembly housing 400 towards the first opening 371a in the lateral direction X-X.

In some embodiments, as shown in FIGS. 6A to 6D, the subassembly housing 400 may include a first snap member 405b disposed at the fifth face 405 and a second snap member 406b disposed at the sixth face 406. As shown in FIGS. 9B to 9D, the member 300 may include a first recess 313 recessed into the top wall 310 from the first channel 371 and a second recess 323 recessed into the separation wall 380 from the first channel 371. When the first projection 405a and the second projection 406a engage with the end of the first receiving groove 311 and the end of the second receiving groove 381, respectively, the first snap member 405b snaps into the first recess 313 and the second snap member 406b snaps into the second recess 323 to restrict the withdrawal of the subassembly housing 400 towards the second opening 371b in the lateral direction X-X. With the configuration of the projection-receiving groove and the snap member-recess, the member 300 can reliably hold the subassembly housing 400 in the lateral direction X-X, and therefore reliably hold the connector subassembly 100 and the board 200. Furthermore, such a configuration can increase the assembly efficiency of the electrical connector 10.

In some embodiments, the top wall 310 of the member 300 may have an opening 314 extending in the vertical direction Z-Z to enable the first snap member 405b, which is snapped into the first recess 313, to be accessible and released from the exterior, thereby allowing for the withdrawal of the subassembly housing 400 towards the second opening 371b in the lateral direction X-X.

In some embodiments, when the subassembly housing 400 is inserted into the first channel 371, the first projection 405a and the second projection 406a may slide along the corresponding first receiving groove 311 and the corresponding second receiving groove 381, respectively, to guide the movement of the subassembly housing 400 in the lateral direction X-X.

As shown in FIG. 9B, the first receiving groove 311 may include two sidewalls 311a and 311b opposed to each other in the longitudinal direction and a bottom wall 311c extending between the two sidewalls 311a and 311b. As shown in FIG. 9A, the second receiving groove 381 may include two sidewalls 381a and 381b opposed to each other in the longitudinal direction and a bottom wall 318c extending between the two sidewalls 381a and 381b. In some embodiments, the first projection 405a may engage with the two sidewalls 311a and 311b of the corresponding first receiving groove 311, and the second projection 406a may engage with the two sidewalls 381a and 381b the corresponding second receiving groove 381, so as to restrict the movement of the subassembly housing 400 relative to the member 300 in the longitudinal direction Y-Y. With such a configuration, the member 300 can reliably hold the subassembly housing 400 in the longitudinal direction Y-Y, and therefore reliably hold the connector subassembly 100 and the board 200. Furthermore, such a configuration can improve the assembly efficiency of the electrical connector 10. The third face 403 and the fourth face 404 of the subassembly housing 400 can be spaced apart from the first sidewall 350 and the second sidewall 360 of the member 300, respectively, to allow air to flow therethrough, thereby facilitating the dissipation of heat generated by the connector subassembly 100. The subassembly housing 400 may include heat emission holes (not labeled) extending through the third face 403 and the fourth face 404 from the interior in the longitudinal direction Y-Y, respectively.

In some embodiments, the first projection 405a may engage with the bottom wall 311c of the first receiving groove 311 and the second projection 406a may engage with the bottom wall 318c of the second receiving groove 381, so as to restrict the movement of the subassembly housing 400 relative to the member 300 in the vertical direction Z-Z. With such a configuration, the member 300 can reliably hold the subassembly housing 400 in the vertical direction Z-Z, and therefore reliably hold the connector subassembly 100 and the board 200. Furthermore, such a configuration can improve the assembly efficiency of the electrical connector 10.

In some embodiments, as shown in FIGS. 5A to 5C, the board 200 may be connected to the connector subassembly 100 before the connector subassembly 100 is inserted into the first channel 371 of the member 300. Subsequently, the first edge portion 210 of the board 200 may be inserted into the first channel 371 of the member 300 along with the connector subassembly 100. The subassembly housing 400 is accommodated and held within the first channel 371 of the member 300 as described above, so that the board 200 may be held in place relative to the member 300 by the subassembly housing 400. As shown in FIG. 4A, the first edge portion 210 of the board 200 is disposed within the first channel 371. As shown in FIGS. 2A to 2D and 4A, the second edge portion 220 of the board 200 is disposed outside of the member 300 and is aligned with the openings (e.g., the third opening 372a and the fourth opening 372b) of the second channel 372. For example the second edge portion 220 of the board 200 and the second channel 372 of the member 300 are in positions that have the same levels in the vertical direction Z-Z. With such a configuration, the second channel 372 may direct air flowing through the second channel 372 to the second edge portion 220 of the board 200, e.g., to the mating parts between the board 200 and the electrical connector 5 on the board 3, thereby facilitating the dissipation of heat generated at the mating parts. Such a configuration can improve the heat dissipation performance of the electronic system 1.

As shown in FIGS. 3A, 3B, and 4A, the board 200 may include a board body 201 having a first side edge 201a extending in the vertical direction Z-Z, a second side edge 201b extending in the lateral direction X-X, and a corner 203. The first side edge 201a and the second side edge 201b intersect at the corner 203. The first edge portion 210 extends from the first side edge 201a in the lateral direction X-X, and the second edge portion 220 extends from the second side edge 201b in the vertical direction Z-Z and beyond the first edge portion 210. Thus, the first edge portion 210 and the second edge portion 220 extend from the board body 201 in orthogonal directions. The board body 201 of the board 200 defines a main plane perpendicular to the longitudinal direction Y-Y (e.g., parallel to both the lateral direction X-X and the vertical direction Z-Z), and the first edge portion 210 and the second edge portion 220 extend in the main plane. The board body 201 may include a third edge portion 205 extending from the board body 201 oppositely to the second edge portion 220 in the vertical direction Z-Z and beyond the first edge portion 210. The third edge portion 205 may include two surfaces 205a and 205b opposite to each other in the longitudinal direction Y-Y, and a third side edge 205c extending between the two surfaces 205a and 205b and in the lateral direction X-X.

In some embodiments, the board body 201 of the board 200 may be held by the member 300 to improve the mechanical reliability of the electrical connector 10. For example, when the electrical connector 10 is connected to the electrical connector 5 on the board 3 or when the electrical connector 10 is separated from the electrical connector 5, the member 300 can provide support to the board body 201 of the board 200 to reliably hold the board 200 in place relative to the member 300.

In some embodiments, as shown in FIG. 9D, the end of the separation wall 380 is indented into the member 300 relative to the second side face 340 in the lateral direction X-X to leave a space 373 between the first channel 371 and the second channel 372 that communicates the first channel 371 and the second channel 372 with each other. As shown in FIGS. 9A to 9D, the member 300 may include a shelf 390 disposed in the second channel 372. The shelf 390 may be spaced apart from the separation wall 380 in the vertical direction Z-Z. The shelf 390 may divide the air flow in the second channel 372 into two portions, one of which flows towards the first edge portion 210 of the board 200 and the other of which flows towards the second edge portion 220 of the board 200.

As shown in FIG. 4A, when the subassembly housing 400 and the first edge portion 210 of the board 200 are inserted into the first channel 371, a segment of the board body 201 including the first side edge 201a is disposed in the member 300 and extends from the first channel 371 through the space 373 into the second channel 372. The corner 203 is disposed in the second channel 372 and is supported by the shelf 390 in the vertical direction Z-Z. As illustrated, the shelf 390 supports a segment of the second side edge 201b at the corner 203 in the vertical direction Z-Z. With such a configuration, the shelf 390 can provide support and position limitation in the vertical direction Z-Z on one side of the panel body 201 (e.g., at the corner 203).

In some embodiments, the member 300 may include a third receiving groove 315 recessed into the top wall 310 from the first channel 371 and extending in the lateral direction X-X. As shown in FIGS. 9B and 9D, the third receiving groove 315 may be one and the same receiving groove as one of the first receiving grooves 311. It should be appreciated that the present disclosure may not be limited thereto. The third receiving groove 315 may be an additional groove. The third receiving groove 315 may include two sidewalls opposed to each other in the longitudinal direction Y-Y (e.g., the sidewall 311a and the sidewall 311b in the drawings) and a bottom wall (e.g., the bottom wall 311c in the drawings) extending between the two sidewalls. As shown in FIGS. 4A and 4B, at least a portion of the third edge portion 205 is received in the third receiving groove 315 so that the third side edge 205c engages with the bottom wall of the third receiving groove 315. With such a configuration, the top wall 310 of the member 300 can provide support and position limitation in the vertical direction Z-Z on the other side of the board body 201 (e.g., at the third side edge 205c).

The member 300 can reliably hold the board body 201 in the vertical direction Z-Z by the engagement between the shelf 390 and the second side edge 201b and the engagement between the third side edge 205c of the third edge portion 205 and the bottom wall of the third receiving groove 315. Such a configuration can improve the mechanical reliability of the electrical connector 10.

It should be appreciated that in some embodiments, the edge of the third edge portion 205 may be flush with the edge of the first edge portion 210 in the vertical direction Z-Z. For example the third side edge 205c of the third edge portion 205 may be flush with the first end 213 of the first edge portion 210. In this case, the third side edge 205c of the third edge portion 205 may engage with a surface of the top wall 310 of the member 300.

In some embodiments, as shown in FIGS. 9A to 9C, the shelf 390 may include a support face 390a for supporting the segment of the second side edge 201b and a pair of projections 390b and 390c protruding from the support face 390a in the vertical direction Z-Z. The projections 390b and 390c may be in the form of ribs, respectively, and each extend in the lateral direction X-X. The projections 390b and 390c are spaced apart from each other in the longitudinal direction Y-Y. As shown in FIG. 4B, the projections 390b and 390c may receive and hold the corner 203 therebetween. With such a configuration, it is possible to provide support and position limitation to the board body 201 in the longitudinal direction Y-Y, so as to restrict the movement of the board body 201 relative to the member 300 in the longitudinal direction Y-Y. Such a configuration can improve the mechanical reliability of the electrical connector 10.

In some embodiments, as shown in FIGS. 4A and 4B, when at least a portion of the third edge portion 205 is received in the third receiving groove 315, the two surfaces 205a and 205b of the third edge portion 205 engage with the two sidewalls of the third receiving groove 315, respectively. With such a configuration, it is possible to provide support and position limitation to the board body 201 in the longitudinal direction Y-Y, so as to restrict the movement of the board body 201 relative to the member 300 in the longitudinal direction Y-Y. Such a configuration can improve the mechanical reliability of the electrical connector 10.

In some embodiments, as shown in FIGS. 9A and 9D, an end of the separation wall 380 adjacent to the second side face 340 may include a notch 383 recessed into the separation wall 380 from the space 373 in the lateral direction X-X. As shown in FIGS. 4A and 4B, a segment of the first side edge 201a of the board body 201 may be received in the notch 383 to restrict the movement of the board body 201 relative to the member 300 in the longitudinal direction Y-Y. With such a configuration, it is possible to provide support and position limitation to the board body 201 in the longitudinal direction Y-Y, so as to reliably hold the board body 201 relative to the member 300. Such a configuration can improve the mechanical reliability of the electrical connector 10.

In some embodiments, as shown in FIGS. 9B and 9D, the member 300 may include a first protrusion 301 protruding from an outer surface 320a of the bottom wall 320 in the vertical direction Z-Z and configured to be placed on the surface 3a of the board 3. The first protrusion 301 may be integrally formed with the bottom wall 320. As shown in FIG. 1, when the member 300 is secured on the surface 3a of the board 3, the first protrusion 301 may space the outer surface 320a of the bottom wall 320 from the surface 3a of the board 3 by a gap G. With such a configuration, the space on the board 3 occupied by the member 300 can be reduced and the heat dissipation performance of the electronic system 1 can be improved.

With the configuration of the member 300, the mating channel (e.g., the slot 410) of the electrical connector 10 may be disposed at a position with a higher level. In some embodiments, as shown in FIG. 2E, a vertical distance D from a midpoint 410a of the slot 410 in the vertical direction Z-Z to the bottom surface 301a of the first protrusion 301 of the member 300 may be greater than 25 mm. For example, the vertical distance D may be 26.5 mm. In some embodiments, the vertical distance D from the midpoint 410a of the slot 410 to the outer surface 320a of the bottom wall 320 of the member 300 may be greater than 25 mm. For example, the vertical distance may be 26.5 mm.

In some embodiments, as shown in FIGS. 9B and 9C, the member 300 may include a second protrusion 302 protruding outwardly from the first sidewall 350 in the longitudinal direction Y-Y, and a third protrusion 303 protruding outwardly from the second sidewall 360 in the longitudinal direction Y-Y. The second protrusion 302 and the third protrusion 303 may be formed integrally with the first sidewall 350 and the second sidewall 360, respectively. The second protrusion 302 and the third protrusion 303 each include a mounting hole 304 extending in the vertical direction Z-Z for receiving a fastener (not shown) for securing the member 300 to the board 3. For example, the mounting holes 304 may be threaded holes, and the fasteners may be threaded fasteners, such as bolts or screws. The board 3 may include mating mounting holes (not shown), such as threaded holes or through holes. The fasteners may be inserted through the corresponding mounting holes 304 of the member 300 into the mating mounting holes of the board 3. With such a configuration, the electrical connector 10 and the board 3 can be reliably and securely connected together with each other.

In some embodiments, as shown in FIGS. 9B and 9C, the second protrusion 302 and the third protrusion 303 may be offset from each other in the longitudinal direction Y-Y. With such a configuration, when the plurality of electrical connectors 10 are mounted on the board 3, the protrusions of two adjacent electrical connectors 10 may be offset from each other. In this way, the plurality of electrical connectors 10 may be disposed on the board 3 at a higher density to realize a high-density and small-pitch connector layout.

FIGS. 10A and 10B illustrate an electronic system 1′ including the board 3 and three electrical connectors 10 mounted on the board 3. As shown in FIG. 10B, when the three electrical connectors 10 are mounted on the board 3, the three electrical connectors 10 are arranged in a row in the longitudinal direction Y-Y so that the slots 410 of the subassembly housings 400 of the first electrical connectors 10 face towards one and the same direction. Since the second protrusion 302 and the third protrusion 303 of each electrical connector 10 are offset from each other in the longitudinal direction Y-Y, the protrusions 302 and 303 of every two adjacent electrical connectors 10 may be adjacent to and offset from each other. With such an arrangement, the three electrical connectors 10 may be arranged on the board 3 at a higher density. The pitch P between two adjacent electrical connectors 10 may be less than 11 mm or less than 10 mm, for example, 9.2 mm. The pitch P may refer to the pitch between the longitudinal center lines (which are parallel to the vertical direction Z-Z) of the slots 410 of two adjacent first electrical connectors 10.

Having thus described several aspects of several embodiments of electrical connectors and systems, it is to be appreciated that various alterations, modifications, and improvements will readily occur to those skilled in the art. Such alterations, modifications, and improvements are intended to be part of this disclosure, and are intended to be within the spirit and scope of the invention. While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

For example, although the board 200 is described above as being connected to connector subassembly 100 before the connector subassembly 100 is inserted into the member 300, it should be appreciated that the present disclosure may not be limited thereto. In some embodiments, the board 200 may also be inserted into the member 300 and connected to the connector subassembly 100 after the connector subassembly 100 is inserted into the member 300. The member 300 may hold the board 200 and the subassembly housing 400 to be fixed relative to each other.

As another example, although the connector subassembly 100, the board 200, and the member 300 are described above as components of the connector subassembly 100, it should be appreciated that this is only for the convenience of description. In some embodiments, the connector subassembly 100 and the board 200 may form an electronic assembly, or the connector subassembly 100 and the member 300 may form an electronic assembly.

As a further example, although the subassembly housing 400 and the plurality of conductive elements 510 are described above as components of the connector subassembly 100, it should be appreciated that this is only for convenience of description. In some embodiments, the concept of connector subassembly 100 may be omitted.

While various inventive embodiments have been described and illustrated, those of ordinary skill in the art will readily envision a variety of other means and/or structures for performing the function and/or obtaining the results and/or one or more of the advantages described, and each of such variations and/or modifications is deemed to be within the scope of the inventive embodiments described. More generally, those skilled in the art will readily appreciate that all parameters, dimensions, materials, and configurations described are meant to be examples and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure may be directed to each individual feature, system, system upgrade, and/or method described. In addition, any combination of two or more such features, systems, and/or methods, if such features, systems, system upgrade, and/or methods are not mutually inconsistent, is included within the inventive scope of the present disclosure.

Further, though some advantages of the present invention may be indicated, it should be appreciated that not every embodiment of the invention will include every described advantage. Some embodiments may not implement any features described as advantageous. Accordingly, the foregoing description and drawings are by way of example only.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

In the claims, as well as in the specification above, use of ordinal terms such as “first,” “second,” “third,” etc. does not by itself connote any priority, precedence, or order of one element over another or the temporal order in which acts of a method are performed, but are used merely as labels to distinguish one element having a certain name from another element having a same name (but for use of the ordinal term) to distinguish the elements.

What is claimed is:

1. An electrical connector, comprising:
a housing comprising a slot;
a plurality of conductive elements, each of the plurality of conductive elements comprising a first mating end disposed in the slot of the housing, and a second mating end opposite to the first mating end; and
a board coupled to the plurality of conductive elements, the board comprising:
a first edge portion comprising a plurality of first contact pads aligned in a vertical direction, each of the plurality of first contact pads engaging a respective conductive element of the plurality of conductive elements, and
a second edge portion disposed beyond the first edge portion in the vertical direction and a plurality of second contact pads aligned in a lateral direction perpendicular to the vertical direction.

2. The electrical connector of claim 1, wherein:
the second edge portion of the board is disposed below the slot of the housing.

3. The electrical connector of claim 1, wherein:
the second mating ends of the plurality of conductive elements are arranged in two rows each extending in the vertical direction and spaced apart from each other in a longitudinal direction perpendicular to the vertical direction and the lateral direction; and
the first edge portion is disposed between the two rows of the second mating ends.

4. The electrical connector of claim 1, wherein:
the housing comprises a first arm portion and a second arm portion spaced apart from each other in the vertical direction;
the second mating ends of the plurality of conductive elements are disposed between the first arm portion and the second arm portion; and
the first edge portion of the board is held by the first arm portion and the second arm portion therebetween.

5. The electrical connector of claim 4, wherein:
each of the first arm portion and the second arm portion comprises a passage extending therethrough in a longitudinal direction perpendicular to both the lateral direction and the vertical direction; and
the electrical connector comprises a plurality of locking members each disposed in the passage of a respective arm portion and engaging the first edge portion of the board.

6. The electrical connector of claim 5, wherein:
the first edge portion of the board comprises a plurality of locking pads disposed, each of the plurality of locking pads engaging a respective locking member of the plurality of locking members.

7. The electrical connector of claim 1, comprising:
a member comprising a first channel and a second channel each extending in the lateral direction and aligned with each other in the vertical direction, wherein:
the housing is accommodated within the first channel of the member.

8. The electrical connector of claim 7, wherein:
the first edge portion of the board is disposed within the first channel of the member; and
the second edge portion of the board is disposed outside of the member and aligned with the second channel of the member.

9. The electrical connector of claim 8, wherein:
the board comprises a corner disposed between the first edge portion and the second edge portion; and
the member comprises a shelf disposed in the second channel and supporting the corner of the board.

10. The electrical connector of claim 7, wherein:
the member comprises a bottom surface configured to engage a surface of another board; and
a distance from a midpoint of the slot of the housing to the bottom surface of the member is 26.5 mm in the vertical direction.

11. An electrical connector, comprising:
a member comprising a first channel and a second channel;
a housing disposed in the first channel of the member, the housing comprising a card-receiving slot;
a plurality of conductive elements, each of the plurality of conductive elements comprising a first mating end disposed in the slot of the housing, and a second mating end disposed outside the slot of the housing; and
a board comprising a first edge portion comprising a plurality of first contact pads contacting respective conductive elements of the plurality of conductive elements, and a second edge portion aligned with an opening of the second channel of the member and comprising a plurality of second contact pads.

12. The electrical connector of claim 11, wherein:
the member comprises a top wall and a bottom wall opposite to each other in a vertical direction, and a separation wall disposed between the top wall and the bottom wall in the vertical direction; and
the housing is held in the first channel by the top wall and the separation wall.

13. The electrical connector of claim 12, wherein:
the member comprises a first receiving groove recessed into the top wall, and a second receiving groove recessed into the separation wall; and
the housing comprises a first end face and a second end face opposite to each other in the vertical direction, and a first projection protruding into the first receiving groove of the member, and a second projection protruding into the second receiving groove.

14. The electrical connector of claim 12, wherein:
the board comprises a board body having a corner, a first side edge extending in the vertical direction, and a second side edge extending in a lateral direction perpendicular to the vertical direction and intersecting the first side edge at the corner; and
the first edge portion extends from the first side edge in the lateral direction, and the second edge portion extends from the second side edge in the vertical direction and beyond the first edge portion.

15. The electrical connector of claim 14, wherein:
the separation wall of the member is indented into the member in the lateral direction;
the board body extends from the first channel into the second channel;
the corner is disposed in the second channel; and
the member comprises a shelf disposed in the second channel and at least partially supporting the second side edge at the corner.

16. The electrical connector of claim 15, wherein:
the board body comprises a third edge portion extending beyond the first edge portion in the lateral direction;
the member comprises a receiving groove recessed into the top wall; and
the third edge portion is at least partially disposed in the receiving groove.

17. The electrical connector of claim 15, wherein:
the separation wall comprises a notch recessed into the separation wall; and
the first side edge of the board body is at least partially disposed in the notch.

18. The electrical connector of claim 12, wherein the member comprises:
a first sidewall and a second sidewall opposite to each other in a longitudinal direction perpendicular to the vertical direction and each extending between the top wall and the bottom wall in the vertical direction;
a first protrusion protruding from the bottom wall in the vertical direction;
a second protrusion protruding outwardly from the first sidewall in the longitudinal direction and comprising a mounting hole extending in the vertical direction; and
a third protrusion protruding outwardly from the second sidewall in the longitudinal direction and offset from the second protrusion in the longitudinal direction, the third protrusion comprising a mounting hole extending in the vertical direction.

19. An electronic system, comprising:
an electrical connector comprising:
a member comprising a first channel and a second channel; and
a housing disposed in the first channel of the member, the housing comprising a card-receiving slot elongated in a vertical direction perpendicular,
wherein the member comprises a first sidewall and a second sidewall opposite to each other in a longitudinal direction perpendicular to the vertical direction, a first protrusion protruding outwardly from the first sidewall in the longitudinal direction and comprising a mounting hole extending in the vertical direction, and a second protrusion protruding outwardly from the second sidewall in the longitudinal direction and offset from the second protrusion in the longitudinal direction, the second protrusion comprising a mounting hole extending in the vertical direction.

20. The electronic system of claim 19, wherein:
the electrical connector is a first electrical connector;
the electronic system comprises a plurality of electrical connectors comprising the first electrical connector, the plurality of electrical connectors aligned in a row in the longitudinal direction; and
a center-to-center pitch between adjacent electrical connectors of the plurality of electrical connectors is 9.2 mm.
